(19) United States
(12) Patent Application Publication
(10) Pub. No.: US 2013/0069121 A1
(43) Pub. Date: Mar. 21, 2013

(54) ION SENSOR, DISPLAY DEVICE, METHOD FOR DRIVING ION SENSOR, AND METHOD FOR CALCULATING ION CONCENTRATION

(71) Applicants: Atsuhito Murai, Osaka-shi (JP); Yoshiharu Kataoka, Osaka-shi (JP); Takuya Watanabe, Osaka-shi (JP); Yuhko Hisada, Osaka-shi (JP); Satoshi Horiuchi, Osaka-shi (JP)

(72) Inventors: Atsuhito Murai, Osaka-shi (JP); Yoshiharu Kataoka, Osaka-shi (JP); Takuya Watanabe, Osaka-shi (JP); Yuhko Hisada, Osaka-shi (JP); Satoshi Horiuchi, Osaka-shi (JP)

(21) Appl. No.: 13/701,129

(22) PCT Filed: May 18, 2011
(86) PCT No.: PCT/JP2011/061385

§ 371 Date: Dec. 6, 2012

(30) Foreign Application Priority Data
Jun. 3, 2010 (JP) 2010-128169

(51) Int. Cl. H01L 29/772

(52) U.S. Cl. 257/253; 257/E29.242

(57) ABSTRACT

The present invention provides an ion sensor with which an ion concentration in a sample in which both ions are mixed can be measured with high accuracy, a display device, a method for driving the ion sensor, and a method for calculating an ion concentration. The present invention is an ion sensor that includes a field effect transistor. The ion sensor detects one of negative ions and positive ions using the field effect transistor, and consecutively thereafter detects the other of the negative ions and positive ions using the field effect transistor.

### TECHNICAL FIELD

The present invention relates to an ion sensor, a display device, a method for driving an ion sensor, and a method for calculating an ion concentration. More specifically, the present invention relates to an ion sensor that is suitable as an ion sensor that includes a field effect transistor (hereinafter, also referred to as “FET”), a display device that includes the ion sensor, a method for driving the ion sensor, and a method for calculating an ion concentration that uses the ion sensor.

### BACKGROUND ART

A technology of generating positive ions and negative ions (hereinafter, also referred to as “both ions” or simply as “ions”) in the air has recently been found to have an effect of killing bacteria floating in the air and purify the air. An ion generator employing the technology, such as an air purifier, has matched the comfort and the recent trends towards health-conscious lifestyle, and thus has drawn much attention.

Since ions are invisible, checking generation of ions by direct eye-observation is not possible. Still, users of devices such as air purifiers naturally want to know if ions are successfully generated and if the ions generated have a desired concentration.

In this regard, an air conditioner that is equipped with an ion sensor that includes an FET, and that has a display that displays an ion concentration measured with the ion sensor (for example, see Patent Literature 1), a field-effect biosensor (for example, see Patent Literature 2), and a field effect transistor type ion sensor (for example, see Patent Literature 3) and the like have been disclosed.

Because an FET is manufactured by a semiconductor integrated circuit manufacturing process, miniaturization and standardization of an ion sensor that includes an FET are easily performed and mass production thereof is also facilitated.

Further, an ion generating element that is equipped with an ion sensor portion that determines the amount of positive ions and negative ions generated from an ion generation portion, and a display that displays a determined ion amount is known (for example, see Patent Literature 4). In addition, a remote control for an electric home appliance with a built-in ion sensor is known that includes an ion sensor that measures an ion concentration in the atmosphere and a display that displays the current state of the electric home appliance (for example, see Patent Literature 5).

### CITATION LIST

### Patent Literature

Patent Literature 1: JP 10-332164 A
Patent Literature 2: JP 2002-296229 A
Patent Literature 3: JP 2008-215974 A
Patent Literature 4: JP 2003-336872 A
Patent Literature 5: JP 2004-156855 A

### SUMMARY OF INVENTION

### Technical Problem

The inventors discovered that, with respect to a sample in which both ions are mixed, when continuously measuring one type of ion using an ion sensor that includes a thin film device with a low withstand pressure, in some cases a concentration of the one type of ion can not be accurately measured.

For example, in the case of a sample in which both ions are mixed, when only negative ions are continuously measured using an ion sensor that includes an FET, in some cases the measurement is inhibited by positive ions and a negative ion concentration can not be measured accurately. This phenomenon and the cause thereof will now be described using FIG. 22 and FIG. 23.

First, the configuration of an ion sensor including an FET that the inventors used is described. FIG. 22 is a view of an equivalent circuit that illustrates an ion sensor having an N-channel thin film transistor (hereinafter, also referred to as “TFT”) as an FET. An input line 27 is connected to a drain electrode of the TFT 50. A high voltage (+10 V) or a low voltage (0 V) is applied to the input line 27, and the voltage of the input line 27 is taken as Vdd. An output line 21c is connected to a source electrode. The voltage of the output line 21c is taken as Vout. An ion sensor antenna 41c is connected through a connection line 22c to a gate electrode of the TFT 50. A reset line 2i is connected to the connection line 22c. A point of intersection (node) between the line 22c and the line 2i is taken as a node-Z. The reset line 2i is a line for resetting the node-Z, that is, a voltage between the gate of the TFT 50 and the antenna 41c. A high voltage (+20 V) or a low voltage (−10 V) is applied to the reset line 2i, and the voltage of the reset line 2i is taken as Vrst. A ground (GND) is connected through a storage capacitor 43c to the connection line 2i.

Next, the operational mechanism of the above described ion sensor is described. In the initial state, Vrst is set to a low voltage (−10 V) and Vdd is set to a low voltage (0 V). Before starting measurement of a negative ion concentration, a high voltage (+20 V) is first applied to the reset line 2i and the voltage of the antenna 41c (voltage of the node-Z) is reset to +20 V. After the voltage of the node-Z has been reset, the reset line 2i is held in a high impedance state. Subsequently, when introduction of ions begins and negative ions are collected by the antenna 41c, the voltage of the node-Z that has been reset to +20 V, that is, charged to a positive voltage, is neutralized by the negative ions and decreases (sensing operation). The higher the negative ion concentration is, the faster the speed at which the voltage decreases. After a predetermined time period has elapsed since introduction of ions began, a high voltage (+10 V) is temporarily applied to the input line 27. That is, a pulse voltage of +10 V is applied to the input line 27. When the pulse voltage of +10 V is applied to the input line 27, a current Id of the output line 21c varies in accordance with a degree of opening of the gate of the sensor TFT 50, that is, the difference in the voltage of the node-Z. The, negative ion concentration is calculated based on the current Id of the output line 21c.

Next, a measurement result is illustrated. FIG. 23 is a graph that shows results obtained by measuring negative ion concentrations of samples in which the mixture ratios of both ions were different using the ion sensor illustrated in FIG. 22.

Five kinds of gases were measured as the samples, namely, dry air (DA) that did not contain both ions, air containing 1400×10³ ions/cm³ of negative ions and 2000×10³ ions/cm³ of positive ions, air containing 1400×10³ ions/cm³ of negative ions and 1300×10³ ions/cm³ of positive ions, air containing 1400×10³ ions/cm³ of negative ions and 800×10³ ions/cm³ of positive ions, and air containing 1400×10³ ions/cm³ of negative ions and 600×10³ ions/cm³ of positive ions.

As shown in FIG. 23, the results show that the sensor output (sensitivity curve) varies significantly depending on the total amount of both ions and the balance between both ions (abundance ratio). Irrespective of the fact that the negative ion concentration of each of the four kinds of samples excluding DA was 1400×10³ ions/cm³, the Id value for a time period t was different for the four kinds of samples. The greater the amount of positive ions in a sample, the greater the degree to which a decrease in Id was suppressed. It is considered that the reason is that the greater the amount of positive ions, the greater the degree to which adsorption of negative ions onto the ion sensor antenna 41c was inhibited by positive ions.

Thus, since a reaction between the ion sensor antenna and the ions that are the measurement object is inhibited by ions of reverse polarity to the ions that are the measurement object, it is not possible to measure with high accuracy the concentration of ions that are the measurement object in a sample in which both ions exist, particularly in a sample in which there is a comparatively large amount of ions of reverse polarity to the ions that are the measurement object.

Application of a high voltage (for example, a voltage exceeding 1000 V) to the ion sensor antenna may be considered in order to prevent inhibition by ions of reverse polarity to the ions that are the measurement object. However, thin film devices including FETs and TFTs have a low withstand voltage of several dozen volts, and therefore in a common ion sensor that has an FET, a voltage that is high enough to be capable of preventing inhibition by ions of reverse polarity to the ions that are the measurement object can not be applied to the ion sensor antenna.

The present invention has been made in view of the above described present situation, and an object of the present invention is to provide an ion sensor with which an ion concentration in a sample in which both ions are mixed can be measured with high accuracy, a display device, a method for driving the ion sensor, and a method for calculating an ion concentration.

### Solution to Problem

The inventors conducted various studies regarding ion sensors with which an ion concentration in a sample in which positive ions and negative ions are mixed can be measured with high accuracy, and found that there is a correlation between a concentration ratio between both ions and a sensor output when positive ions or negative ions are detected, and that a concentration of positive and/or negative ions can be calculated with high accuracy based on the sensor output when positive ions are detected and the sensor output when negative ions are detected. Further, the inventors found that by detecting one of negative ions and positive ions using an FET, and consecutively thereafter detecting the other of the negative ions and positive ions using the FET, or by detecting negative ions using a first FET and detecting positive ions using a second FET, as described above, a detection result for positive ions and a detection result for negative ions can be obtained, and as a result the ion concentration can be measured with high accuracy. Having realized that this idea can beautifully solve the above problem, the inventors have arrived at the present invention.

More specifically, one aspect of the present invention provides an ion sensor that includes a field effect transistor (hereinafter, also referred to as “first present invention”), wherein the ion sensor detects one of negative ions and positive ions using the field effect transistor, and consecutively thereafter detects the other of the negative ions and positive ions using the field effect transistor.

The configuration of the first present invention is not especially limited by other components as long as it essentially includes such components.

Another aspect of the present invention provides an ion sensor that includes a first field effect transistor and a second field effect transistor (hereinafter, also referred to as “second present invention”), wherein the ion sensor detects negative ions using the first field effect transistor and detects positive ions using the second field effect transistor.

The configuration of the second present invention is not especially limited by other components as long as it essentially includes such components.

A further aspect of the present invention provides a method for driving an ion sensor that includes a field effect transistor (hereinafter, also referred to as “third present invention”), wherein the driving method detects one of negative ions and positive ions using the field effect transistor, and consecutively thereafter detects the other of the negative ions and positive ions using the field effect transistor.

The configuration of the third present invention is not especially limited by other components as long as it essentially includes such components.

A further aspect of the present invention provides a method for driving an ion sensor that includes a first field effect transistor and a second field effect transistor (hereinafter, also referred to as “fourth present invention”), wherein the driving method detects negative ions using the first field effect transistor and detects positive ions using the second field effect transistor.

The configuration of the fourth present invention is not especially limited by other components as long as it essentially includes such components.

A further aspect of the present invention provides a method for calculating an ion concentration using an ion sensor that includes a field effect transistor (hereinafter, also referred to as “fifth present invention”), wherein the calculation method includes: a first step of detecting one of negative ions and positive ions using the field effect transistor, and a second step of, consecutively after the first step, detecting the other of the negative ions and positive ions using the field effect transistor.

The configuration of the fifth present invention is not especially limited by other components and steps as long as it essentially includes such components and steps.

A still further aspect of the present invention provides a method for calculating an ion concentration using an ion sensor that includes a first field effect transistor and a second field effect transistor (hereinafter, also referred to as “sixth present invention”), wherein the calculation method includes a first step of detecting negative ions using the first field effect transistor, and a second step of detecting positive ions using the second field effect transistor.

The configuration of the sixth present invention is not especially limited by other components and steps as long as it essentially includes such components and steps.

A further aspect of the present invention provides a method for calculating an ion concentration using an ion sensor that includes at least one field effect transistor (hereinafter, also referred to as “seventh present invention”), wherein the calculation method includes a step of determining at least one of a negative ion concentration and a positive ion concentration using a detection result for negative ions and a detection result for positive ions obtained by the at least one field effect transistor.

The configuration of the seventh present invention is not especially limited by other components and steps as long as it essentially includes such components and steps.

According to the first, third and fifth present inventions, since an ion concentration can be measured using a single ion sensor circuit that includes only one FET, it is possible to miniaturize the ion sensor in comparison to the second, fourth and sixth present inventions.

Further, according to the second, fourth and sixth present inventions, a negative ion-detecting sensor circuit that includes a first FET and a positive ion-detecting sensor circuit that includes a second FET can be appropriately designed in a manner that takes into consideration the kind of ions that are measurement objects of the respective FETs. Further, as described later, negative ions and positive ions can be detected at the same timing. Therefore, according to the second, fourth and sixth present inventions, an ion concentration can be measured with higher accuracy in comparison to the first, third and fifth present inventions.

The present inventions are described in detail hereinafter.

In the first to seventh present inventions, the ion sensor includes at least one FET, the electric resistance of a channel of the FET changes in accordance with an ion concentration that is detected, and the change is detected as a current or voltage change between a source and a drain of the FET.

In the first to seventh present inventions, although the kind of each FET is not particularly limited, a TFT and a MOSFET (metal oxide semiconductor FET) are preferable. A TFT is favorably used in an organic EL (electro-luminescence) display device or liquid crystal display device that employs the active matrix driving method. A MOSFET is favorably used in a semiconductor chip such as an LSI or an IC.

Note that in the second, fourth and sixth present inventions, the kinds of the first FET and the second FET may be the same as or different to each other. Further, in the seventh present invention, when the ion sensor includes a plurality of FETs, the kinds of the respective FETs may be the same as or different to each other.

Any semiconductor material may be used for TFTs. Examples of the material include amorphous silicon (a-Si), polysilicon (p-Si), microcrystalline silicon (μc-Si), continuous grain silicon (CG-Si), and oxide semiconductors. Any semiconductor material may be used for MOSFETs. Examples of the material include silicon.

Preferable embodiments of the first to seventh present inventions are mentioned in more detail below.

In the first and second present inventions, preferably the ion sensor calculates at least one of a negative ion concentration and a positive ion concentration using a detection result for negative ions and a detection result for positive ions. Thus, even if inhibition is caused by ions of reverse polarity to the ions that are the measurement object, it is possible to calculate the ion concentration of the measurement object with high accuracy.

From a similar viewpoint, preferably the third and fourth present inventions calculate at least one of a negative ion concentration and a positive ion concentration using a detection result for negative ions and a detection result for positive ions, and preferably the fifth and sixth present inventions include a third step of calculating at least one of a negative ion concentration and a positive ion concentration using a detection result for negative ions and a detection result for positive ions.

Note that in the first to seventh present inventions, the ions that are measurement objects are not particularly limited, and may be appropriately set depending on the intended use. That is, a concentration of only positive ions or only negative ions may be measured, or the concentrations of both ions may be measured.

In the first to seventh present inventions, preferably the at least one of a negative ion concentration and a positive ion concentration is determined using a previously prepared calibration curve or look-up table (LUT). It is thus possible to simply calculate concentrations of both ions based on measurement results for both ions.

In the first, third and fifth present inventions, preferably the ion sensor further includes a capacitor, and one terminal of the capacitor is connected to a gate electrode of the field effect transistor, and the other terminal of the capacitor receives voltage. Thus, when measuring a current or voltage value between the source and drain of the FET, if the conductivity type of the FET is the N-channel type, the potential-of the gate of the FET can be pushed up to a positive value, and if the conductivity type of the FET is the P-channel type, the potential of the gate of the FET can be pushed down to a negative value. Therefore, in an N-channel FET or a P-channel FET, the potential of the gate can be shifted to a voltage region that is suitable for detecting ions with high accuracy. As a result, it is possible to detect both positive ions and negative ions with high accuracy using only an FET that has either N-channel or P-channel conductivity. Further, since it is sufficient to form only an FET that has either N-channel or P-channel conductivity, manufacturing costs can be reduced.

Although the kind of the capacitor is not particularly limited, preferably the capacitor has a single plate structure. It is possible to form such a capacitor at the same time as an electrode or line of an FET, and thus costs can be reduced.

In the first, third and fifth present inventions, preferably the voltage applied to the other terminal of the capacitor is variable. Since it is thereby possible to appropriately adjust a push-up amount or push-down amount, the potential of the gate can be easily shifted to an optimal voltage region.

In the first to seventh present inventions, preferably the respective FETs include amorphous silicon or microcrystalline silicon. By using the comparatively inexpensive a-Si or μc-Si, it is possible to provide an ion sensor that, while having a low manufacturing cost, can detect both ions with high accuracy.

In the second, fourth and sixth present inventions, as long as an ion concentration of a permissible accuracy can be measured, a timing of detecting negative ions and a timing of detecting positive ions may deviate from each other. However, from the viewpoint of measuring an ion concentration with higher accuracy, in the second present invention, preferably the ion sensor detects positive ions using the second field effect transistor at the same time as detecting negative ions using the first field effect transistor. From a similar viewpoint, preferably the fourth present invention detects positive ions using the second field effect transistor at the same time as detecting negative ions using the first field effect transistor, and preferably in the sixth present invention the first step and the second step are performed at the same time.

Note that the term “at the same time” may refer to substantially the same time, and it need not necessarily refer to times that are strictly the same as long as the times are within a range in which an ion concentration can be measured with a desired accuracy.

In the first, third, and fifth present inventions, it is preferable that the ion sensor further includes an ion sensor antenna (hereinafter also simply referred to as an “antenna”) which is connected to the gate electrode of the field effect transistor. The antenna is a conductive component that detects (captures) ions in the air. Accordingly, the above structure allows the ion sensors to function effectively. More specifically, ions reaching the antenna charge the surface of the antenna, which leads to an electric potential change of the gate electrode of the FET that is connected to the antenna. The change results in a change in the electrical resistance of the channel of the FET.

From a similar viewpoint, in the second, fourth and sixth present inventions, preferably the ion sensor further includes a first ion sensor antenna and a second ion sensor antenna, wherein the first ion sensor antenna is connected to a gate electrode of the first field effect transistor, and the second ion sensor antenna is connected to a gate electrode of the second field effect transistor. Further, in the seventh present invention, preferably the ion sensor further includes at least one ion sensor antenna, and the respective ion sensor antennas are connected to a gate electrode of the at least one field effect transistor.

In the first, third and fifth present inventions, preferably a surface of the ion sensor antenna is covered by a transparent conductive film. It is thereby possible to prevent the antenna from being exposed to the external environment and corroding.

From a similar viewpoint, in the second, fourth and sixth present inventions, preferably a surface of the first ion sensor antenna is covered by a first transparent conductive film, and a surface of the second ion sensor antenna is covered by a second transparent conductive film. Further, in the seventh present invention, preferably each ion sensor antenna is covered by a transparent conductive film.

In the first, third and fifth present inventions, preferably the first FET includes a semiconductor whose properties are changed by light, and the semiconductor is shielded from light by a light-shielding film. Examples of semiconductors whose properties are changed by light include a-Si and μc-Si. Accordingly, in order to use these semiconductors in the ion sensor, it is preferable to shield the semiconductor from light to ensure that the properties thereof do not change. Thus, it is possible to favorably use a semiconductor whose properties are changed by light in the ion sensor by shielding the semiconductor from light.

From a similar viewpoint, in the second, fourth and sixth present inventions, preferably the first FET includes a first semiconductor whose properties are changed by light, with the first semiconductor being shielded from light by a first light-shielding film, and the second FET includes a second semiconductor whose properties are changed by light, with the second semiconductor being shielded from light by a second light-shielding film. Further, in the seventh present invention, preferably the at least one field effect transistor includes a semiconductor whose properties are changed by light, and the semiconductor is shielded from light by a light-shielding film.

In the first, third and fifth present inventions, the ion sensor antenna need not overlap with the channel region of the FET or may overlap therewith. Since an antenna normally does not include a semiconductor whose properties are changed by light, it is not necessary to shield the antenna from light. That is, even if the necessity arises to shield the FET from light, it is not necessary to provide a light-shielding film around the antenna. Accordingly, if the antenna is provided outside the channel region as in the former configuration, the installation location of the antenna can be freely decided without being constrained by the installation location of the FET. Consequently, it is possible to easily form an antenna at a location at which ions can be detected more effectively such as, for example, a location that is close to a flow channel for guiding air to the antenna or a fan. On the other hand, if the antenna is provided within the channel region as in the latter configuration, the gate electrode of the FET can itself be caused to function as an antenna. Therefore, the ion sensor element can be further miniaturized.

From a similar viewpoint, in the second, fourth and sixth present inventions, the first ion sensor antenna may be provided over the channel region of the first FET or need not be provided over the channel region thereof, and the second ion sensor antenna may be provided over the channel region of the second FET or need not be provided over the channel region thereof. Further, in the seventh present invention, the at least one ion sensor antenna may be provided over the channel region of the at least one FET or need not be provided over the channel region thereof.

A further aspect of the present invention provides a display device that is equipped with the first present invention, a display that includes a display-driving circuit, and a substrate (hereinafter, also referred to as “eighth present invention”), wherein the field effect transistor and at least one portion of the display-driving circuit are formed on the same main surface of the substrate.

The configuration of the eighth present invention is not especially limited by other components as long as it essentially includes such components.

A still further aspect of the present invention provides a display device that is equipped with the second present invention, a display that includes a display-driving circuit, and a substrate (hereinafter, also referred to as “ninth present invention”), wherein the first field effect transistor, the second field effect transistor and at least one portion of the display-driving circuit are formed on the same main surface of the substrate.

The configuration of the ninth present invention is not especially limited by other components as long as it essentially includes such components.

According to the eighth and ninth present inventions, an ion sensor can be provided in an empty space such as a picture-frame region of a substrate, and the ion sensor can be formed utilizing a process that forms a display-driving circuit. As a result, it is possible to provide a low-cost and miniaturizable display device that includes the ion sensor of the present invention and a display.

The display devices of the eighth and ninth present inventions may be of any kind, and their suitable examples include flat panel displays (FPDs). Examples of the FPDs include liquid crystal display devices, organic electroluminescence displays, and plasma displays.

The display includes elements for performing the display functions, and includes, for example, display elements and optical films in addition to the display-driving circuit. The display-driving circuit is a circuit for driving the display elements, and includes, for example, circuits such as a TFT array, a gate driver, and a source driver. Particularly, a TFT array is preferably used as the at least one portion of the display-driving circuit.

The display element has a light-emitting function or light-controlling function (shutter function for light), and is provided for each pixel or sub-pixel of the display device.

For example, a liquid crystal display device usually includes a pair of substrates, and has display elements having a light-controlling function between the substrates. More specifically, the display elements of the liquid crystal display device each usually include a pair of electrodes, and liquid crystals placed between the substrates.

An organic electroluminescence display usually has display elements having a light-emitting function on a substrate. More specifically, the display elements of the organic EL display each usually have a structure in which an anode, an organic electroluminescence layer, and a cathode are stacked.

A plasma display usually has a pair of substrates facing each other, and display elements having a light-emitting function which are placed between the substrates.

More specifically, the light-emitting elements of the plasma display usually include a pair of electrodes; a fluorescent material formed on one of the substrates; and rare gas enclosed between the substrates. Preferable embodiments of the eighth and ninth present inventions are mentioned in more detail below.

In the eighth present invention, preferably the FET is a first FET, and the display-driving circuit includes a second FET, and the first FET and the second FET are formed on the same main surface of the substrate. It is thereby possible to make at least part of the materials and processes for forming the first and second FETs the same, and to reduce the costs required to form the first and second FETs.

A device provided with a conventional ion sensor and a display usually utilizes parallel plate electrodes for the ion sensor. For example, the ion sensor of Patent Literature 4 is provided with a plate-shaped accelerating electrode and a plate-shaped capturing electrode which face each other. Such a parallel plate ion sensor cannot be processed easily on the order of micrometers because of the limit of processing accuracy in production. Hence, miniaturization of the ion sensor is difficult. Also on the remote control for electric appliances with a built-in ion sensor described in Patent Literature 5, a parallel plate electrode, consisting of a pair of an ion-accelerating electrode and an ion-capturing electrode, is provided. Miniaturization of such an ion sensor is also difficult. In contrast, use of an FET and an ion sensor antenna for an ion sensor element as in the above structure allows production of the ion sensor element by photolithography. Thereby, the ion sensor can be processed on the order of micrometers, and therefore can be more miniaturized than the parallel plate ion sensors. The electrode gap (gap between the TFT array substrate and counter substrate) in the liquid crystal display device is usually about 3 to 5 μm. In the case that an electrode is provided to each of the TFT array substrate and the counter substrate such that a parallel plate ion sensor is formed, introduction of ions into the gap is considered difficult. Meanwhile, since the ion sensor element including an FET and an antenna as in the above structure eliminates the need for a counter substrate, the display device provided with the ion sensor can be miniaturized.

From a similar viewpoint, in the ninth present invention, preferably the display-driving circuit includes a third FET, and the first FET, the second FET and the third FET are formed on the same main surface of the substrate.

The ion sensor element is an element that is minimum required to convert the ion concentration in the air to an electric, physical amount.

Although the respective kinds of the second FET in the eighth present invention and the third FET in the ninth present invention are not particularly limited, preferably each of the aforementioned FETs is a TFT. A TFT is favorably used in an organic EL display device or liquid crystal display device that employs the active matrix driving method.

Note that, a semiconductor material in a case where the second FET in the eighth present invention and the third FET in the ninth present invention are TFTs is not particularly limited, and a-Si, p-Si, μc-Si, CG-Si and oxide semiconductors may be mentioned as examples thereof. Among those, a-Si and μc-Si are favorable.

In the eighth present invention, preferably the ion sensor antenna has a surface (exposed portion) including a first transparent conductive film, and the display has a second transparent conductive film. In other words, preferably the surface of the ion sensor antenna is covered by the first transparent conductive film, and the display has the second transparent conductive film. Because a transparent conductive film combines electrical conductivity and optical transparency, by adopting the above described form it is possible to favorably use the second transparent conductive film as a transparent electrode of the display. Further, since it is possible to make at least part of the materials or processes for forming the first transparent conductive film and the second transparent conductive film the same as each other, the first transparent conductive film can be formed at a low cost. Further, the antenna can be prevented from being exposed to the external environment and corroding.

The first transparent conductive film and the second transparent conductive film preferably contain the same material(s), and more preferably consist only of the same material(s). Such a structure enables to form the first transparent conductive film at a low cost.

From a similar viewpoint, in the ninth present invention, preferably the first ion sensor antenna has a surface (exposed portion) that includes a first transparent conductive film, the second ion sensor antenna has a surface (exposed portion) that includes a second transparent conductive film, and the display has a third transparent conductive film. In other words, preferably the surface of the first ion sensor antenna is covered by the first transparent conductive film, the surface of the second ion sensor antenna is covered by the second transparent conductive film, and the display has the third transparent conductive film.

The material of each of the first, second, and third transparent conductive films may be any material. For example, indium tin oxide (ITO), indium zinc oxide (IZO), zinc oxide (ZnO), and fluorine-doped tin oxide (FTO) are suitable.

In the eighth present invention, preferably the first FET includes a semiconductor whose properties are changed by light, the semiconductor is shielded from light by a first light-shielding film, and the display has a second light-shielding film. Therefore, for example, when a liquid crystal display device or an organic EL display is applied as the display device of the present invention, a second light-shielding film can be provided at a boundary between each pixel or sub-pixel of the display to suppress color mixing. Further, since it is possible to make at least part of the materials or processes for forming the first light-shielding film and the second light-shielding film the same as each other, the first light-shielding film can be formed at a low cost. Further, it is possible to favorably use a semiconductor whose properties are changed by light in the ion sensor also, and not just in the display.

It is preferable that the first light-shielding film and the second light-shielding film include the same material(s), and it is more preferable that the first light-shielding film and the second light-shielding film are constituted by only the same material(s). It is thereby possible to form the first light-shielding film at a lower cost.

The first light-shielding film shields the first FET from light outside the display device (external light) and/or light inside the display device. Examples of the light inside the display device include reflected light produced inside the display device. In the case that the display device is a spontaneous light emission display device such as an organic EL display and a plasma display, examples of the light inside the display device include light emitted from the light-emitting elements provided in the display device. Meanwhile, in the case of a non-spontaneous light emission liquid crystal display device, examples of the light inside the display device include light from the backlight. The reflected light produced inside the display device is about several tens of lux, and the influence on the first FET is comparatively small. Examples of the external light include sunlight and interior illumination (e.g., fluorescent lamp). The sunlight is 3000 to 100000 Lx, and the interior fluorescent lamp at the time of actual use (except for use in a dark room) is 100 to 3000 Lx. Both lights greatly influence the first FET. The first light-shielding film preferably shields the first FET from at least the external light, and more preferably blocks both the external light and the light inside the display device.

From a similar viewpoint, in the ninth present invention, preferably the first FET includes a first semiconductor whose properties are changed by light, the first semiconductor is shielded from light by a first light-shielding film, the second FET includes a second semiconductor whose properties are changed by light, the second semiconductor is shielded from light by a second light-shielding film, and the display has a third light-shielding film. Further, the first light-shielding film is preferably a film that shields the first FET from at least outside light and more preferably is a film that shields the first FET from both outside light and light inside the display device, and the second light-shielding film is a film that shields the second FET from at least outside light and more preferably is a film that shields the second FET from both outside light and light inside the display device.

In the eighth and ninth present inventions, preferably at least one portion of the ion sensor and at least one portion of the display-driving circuit are connected to a common power supply. By using a common power supply, in comparison to a configuration in which the ion sensor and the display have separate power supplies, it is possible to reduce costs required for forming a power supply and also decrease the amount of space required for power supplies. More specifically, in the eighth present invention, preferably at least the source or drain of the FET and the gate of a TFT of a TFT array are connected to a common power supply. In the ninth present invention, preferably the source or drain of the first FET, the source or drain of the second FET, and the gate of a TFT of a TFT array are connected to a common power supply.

The eighth and ninth present inventions may be used for any product. Suitable examples of the product include non-portable displays such as displays for televisions and personal computers. To such a non-portable display, the ion concentration in the indoor environment in which the display is placed can be displayed. The suitable examples also include portable devices such as cell phones and personal digital assistants (PDAs). With such a product, the ion concentration at various places can be measured easily. The suitable examples further include ion generators provided with a display. Such an ion generator can show on the display the concentration of ions emitted from the ion generator.

### Advantageous Effects of Invention

According to the present invention, it is possible to provide an ion sensor that can measure with high accuracy an ion concentration in a sample in which both ions are mixed, a display device, a method for driving the ion sensor, and a method for calculating an ion concentration.

### BRIEF DESCRIPTION OF DRAWINGS

FIG. 1 is a block diagram of an ion sensor and a display device according to Embodiments 1 to 4.

FIG. 2 is a schematic cross-sectional view illustrating a cross section of the ion sensor and the display device according to Embodiments 1 to 4.

FIG. 3 is a schematic cross-sectional view illustrating a cross section of an ion sensor and a display device according to Embodiment 1.

FIG. 4 is an equivalent circuit illustrating an ion sensor circuit and a portion of a TFT array according to Embodiment 1.

FIG. 5 is a timing chart of the ion sensor circuit according to Embodiment 1.

FIG. 6 is a schematic cross-sectional view illustrating a cross section of an ion sensor and a display device according to Embodiments 2 to 4.

FIG. 7 is an equivalent circuit illustrating an ion sensor circuit and a portion of a TFT array according to Embodiment 2.

FIG. 8 is a timing chart of an ion sensor circuit according to Embodiment 2.

FIG. 9 is a timing chart of an ion sensor circuit according to Embodiment 2.

FIG. 10 is an equivalent circuit illustrating an ion sensor circuit and a portion of a TFT array according to Embodiment 3.

FIG. 11 is a timing chart of an ion sensor circuit according to Embodiment 3.

FIG. 12 is a timing chart of an ion sensor circuit according to Embodiment 3.

FIG. 13 is a curve (calibration curve) that illustrates a relation between an Id(−) and a negative ion concentration.

FIG. 14 is a curve (calibration curve) that illustrates a relation between an Id(+) and a positive ion concentration.

FIG. 15 is a curve (calibration curve) that illustrates a relation between an Id(−) and a negative ion concentration.

FIG. 16 is a curve (calibration curve) that illustrates a relation between an Id(+) and a positive ion concentration.

FIG. 17 is a curve (calibration curve) that illustrates a relation between an Id(−) and a negative ion concentration.

FIG. 18 is a curve (calibration curve) that illustrates a relation between an Id(+) and a positive ion concentration.

FIG. 19 is an equivalent circuit illustrating an ion sensor circuit and a portion of a TFT array according to Embodiment 4.

FIG. 20 is a timing chart of an ion sensor circuit according to Embodiment 4.

FIG. 21 is a timing chart of an ion sensor circuit according to Embodiment 4.

FIG. 22 is an equivalent circuit illustrating an ion sensor having an N-channel TFT.

FIG. 23 is a graph illustrating results obtained by measuring negative ion concentrations of samples with different mixture ratios of both ions, using an ion sensor having an N-channel TFT.

FIG. 24 is an equivalent circuit illustrating a portion of an ion sensor circuit according to Embodiment 1.

FIG. 25 is an equivalent circuit illustrating a portion of a different ion sensor circuit according to Embodiment 1.

FIG. 26 is an LUT according to Embodiments 1 to 4.

### DESCRIPTION OF EMBODIMENTS

The present invention is described in more detail based on the following embodiments, with reference to the drawings. The present invention is not limited to the embodiments.

### Embodiment 1

The present embodiment is described based on examples of an ion sensor including N-channel TFTs and configured to detect ions in the air, and a liquid crystal display device including the ion sensor. FIG. 1 is a block diagram of an ion sensor and a display device according to the present embodiment.

A display device 110 according to the present embodiment is a liquid crystal display device, and includes an ion sensor 120 (ion sensor portion) for measuring the ion concentration in the air, and a display 130 for displaying various images. The display 130 is provided with a display-driving circuit 115 that includes a display-driving TFT array 101, a gate driver (scanning signal line-driving circuit for display) 103, and a source driver (image signal line-driving circuit for display) 104. The ion sensor 120 includes an ion sensor driving/reading circuit 105, an arithmetic processing LSI 106, and an ion sensor circuit 107. A power supply circuit 109 is shared by the ion sensor 120 and the display 130. The ion sensor circuit 107 is a circuit that includes at least elements (preferably an FET and an ion sensor antenna) required to convert the ion concentration in the air to an electric physical amount, and has a function of detecting (capturing) ions.

The display 130 has the same circuit structure as a conventional active-matrix display device such as a liquid crystal display device. That is, images are displayed in a region with the TFT array 101 formed, i.e., in a display region, by line sequential driving.

The function of the ion sensor 120 is summarized below. First, the ions in the air are detected (captured) in the ion sensor circuit 107, and a voltage value corresponding to the detected amount of ions is generated. The voltage value is transmitted to the driving/reading circuit 105 where the value is converted into a digital signal. The signal is transmitted to the LSI 106, such that the ion concentration is calculated by a certain calculation method, and display data for displaying the calculation result in the display region is generated. The display data is transmitted to the TFT array 101 through a source driver 104, and the ion concentration corresponding to the display data is eventually displayed. The power supply circuit 109 supplies electric power to the TFT array 101, the gate driver 103, the source driver 104, and the driving/reading circuit 105. The driving/reading circuit 105 controls the later-described push-up/push-down line, reset line, and input line as well as the above functions, and supplies a certain amount of electric power to each line in desired timing.

The driving/reading circuit 105 may be included in another circuit such as the ion sensor circuit 107, the gate driver 103, and the source driver 104, and may be included in the LSI 106.

In the present embodiment, the arithmetic processing may be performed using software that functions on a personal computer (PC) in place of the LSI 106.

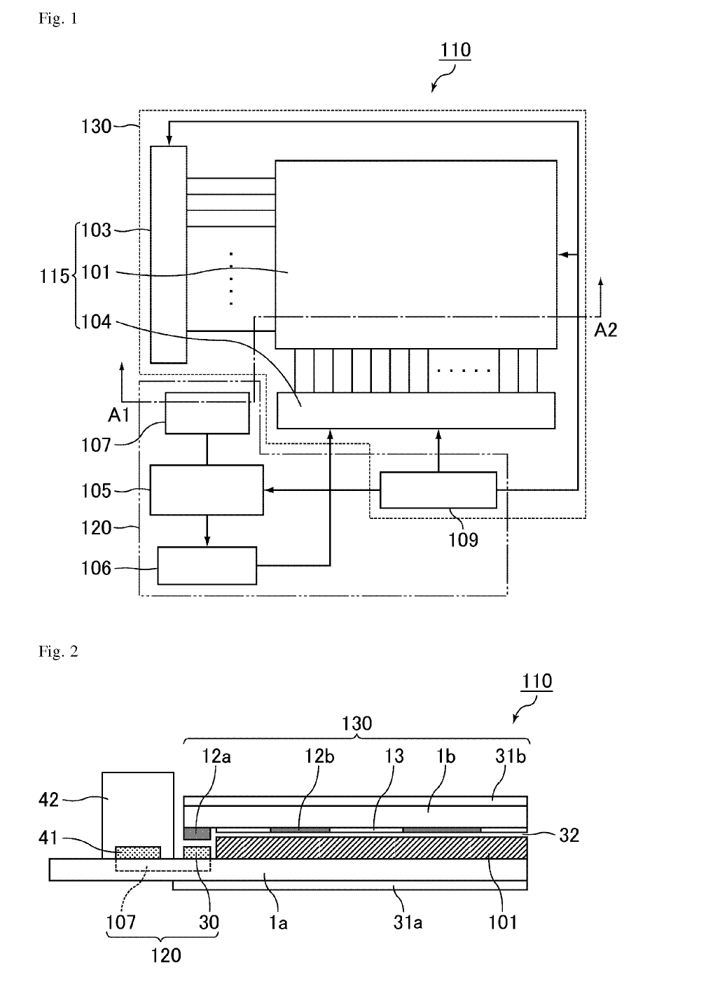

The structure of the display device 110 is described using FIG. 2. FIG. 2 is a schematic cross-sectional view of the ion sensor and the display device which were cut along the line A1-A2 illustrated in FIG. 1. The ion sensor 120 is provided with the ion sensor circuit 107, an air ion lead-in/lead-out path 42, a fan (not illustrated), and a light-shielding film 12a. The ion sensor circuit 107 contains the ion sensor element that includes a sensor TFT 30 and an ion sensor antenna 41. The display 130 is provided with the TFT array 101 including pixel TFTs 40, a light-shielding film 12b, a color filter 13 including colors such as RGB and RGBY, liquid crystals 32, and polarizers 31a and 31b.

The antenna 41 is a conductive member for detecting (capturing) ions in the air, and is connected to the gate of the sensor TFT 30. The antenna 41 includes a portion to be exposed to the external environment (exposure portion). Ions adhering to the surface (exposure portion) of the antenna 41 change the electric potential of the antenna 41, which changes the electric potential of the gate of the sensor TFT 30. As a result, the electric current and/or voltage between the source and drain in the sensor TFT 30 change(s). Thus, an ion sensor element including the antenna 41 and the sensor TFT 30 can be miniaturized compared to the conventional parallel plate ion sensor.

The lead-in/lead-out path 42 is a path for efficiently ventilating the space above the antenna 41. The fan blows air from the observation side to the depth side of FIG. 2, or from the depth side to the observation side.

The display device 110 is provided with two insulating substrates 1a and 1b which face each other in the most part, and the liquid crystals 32 disposed between the substrates 1a and 1b. The sensor TFT 30 and the TFT array 101 are provided on the main surface on the liquid crystal side of the substrate 1a (TFT array substrate) in the region where the substrates 1a and 1b face each other. The TFT array 101 includes pixel TFTs 40 arranged in a matrix state. The antenna 41, lead-in/lead-out path 42, and fan are arranged on the liquid crystal-side main surface of the substrate 1a in the region where the substrates 1a and 1b do not face each other. In this way, the antenna 41 is formed outside the channel regions of the sensor TFT 30. Thereby, the antenna 41 can be easily arranged near the lead-in/lead-out path 42 and the fan, efficiently sending air to the antenna 41. Also, the sensor TFT 30 and the light-shielding film 12a are formed at the end (picture-frame region) of the display 130. The arrangement leads to effective use of the space in the picture-frame region, and therefore the ion sensor circuit 107 can be formed without a change of the size of the display device 110.

On the one same main surface of the substrate la, at least the sensor TFT 30 and the ion sensor antenna 41 included in the ion sensor circuit 107, and the TFT array 101 included in the display-driving circuit 115 are formed. Accordingly, the sensor TFT 30 and the ion sensor antenna 41 can be formed using the process of forming the TFT array 101.

The light-shielding films 12a and 12b and the color filter 13 are provided on the liquid crystal-side main surface of the substrate 1b (counter substrate) in the region where the substrates 1a and 1b face each other. The light-shielding film 12a is formed at a position facing the sensor TFT 30, and the light-shielding film 12b and the color filter 13 are formed at a position facing the TFT array 101. The sensor TFT 30 includes a-Si which is a semiconductor whose properties are changed by light, as described in more detail later. Shielding the sensor TFT 30 from light with the light-shielding film 12a enables to reduce the property change of a-Si, i.e., the output property change of the sensor TFT 30. Thereby, the ion concentration can be measured with higher precision.

The polarizers 31a and 31b are formed on the respective main surfaces on the opposite side to the liquid crystals (outer side) of the substrates 1a and 1b.

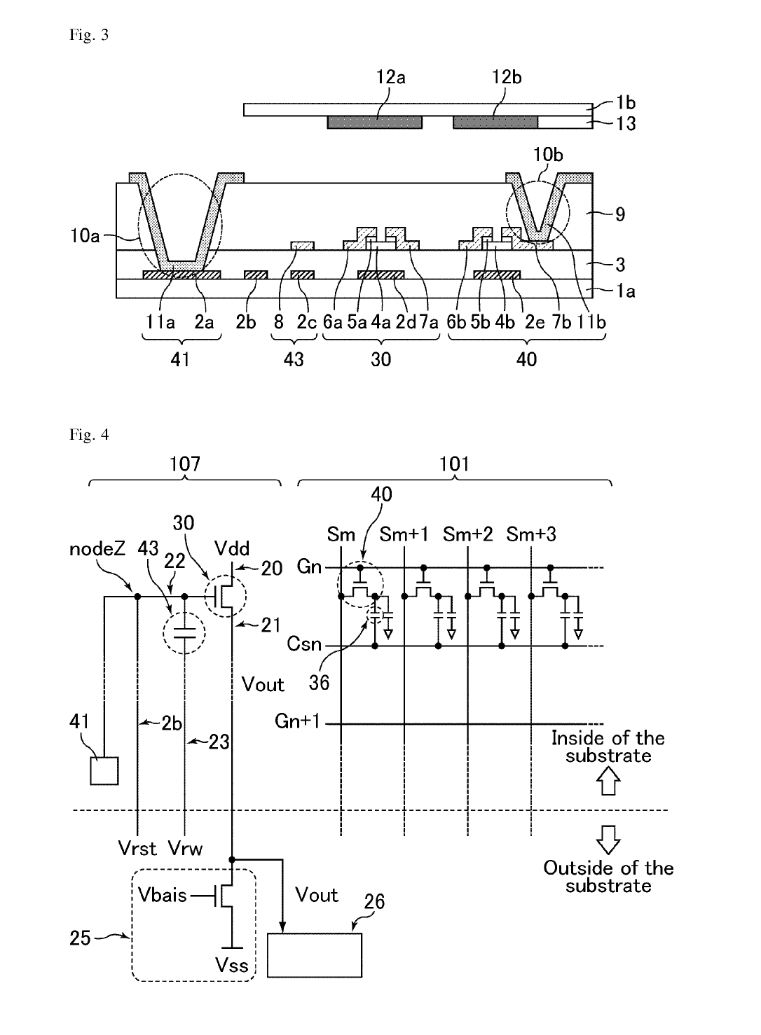

The structure of the display device 110 is described in more detail with reference to FIG. 3. FIG. 3 is a schematic cross-sectional view of the ion sensor and the display device according to the present embodiment.

On the liquid crystal-side main surface of the insulating substrate la, a first conductive layer, an insulating film 3, a hydrogenated a-Si layer, an n+a-Si layer, a second conductive layer, a passivation film 9, and a third conductive layer are stacked in the stated order.

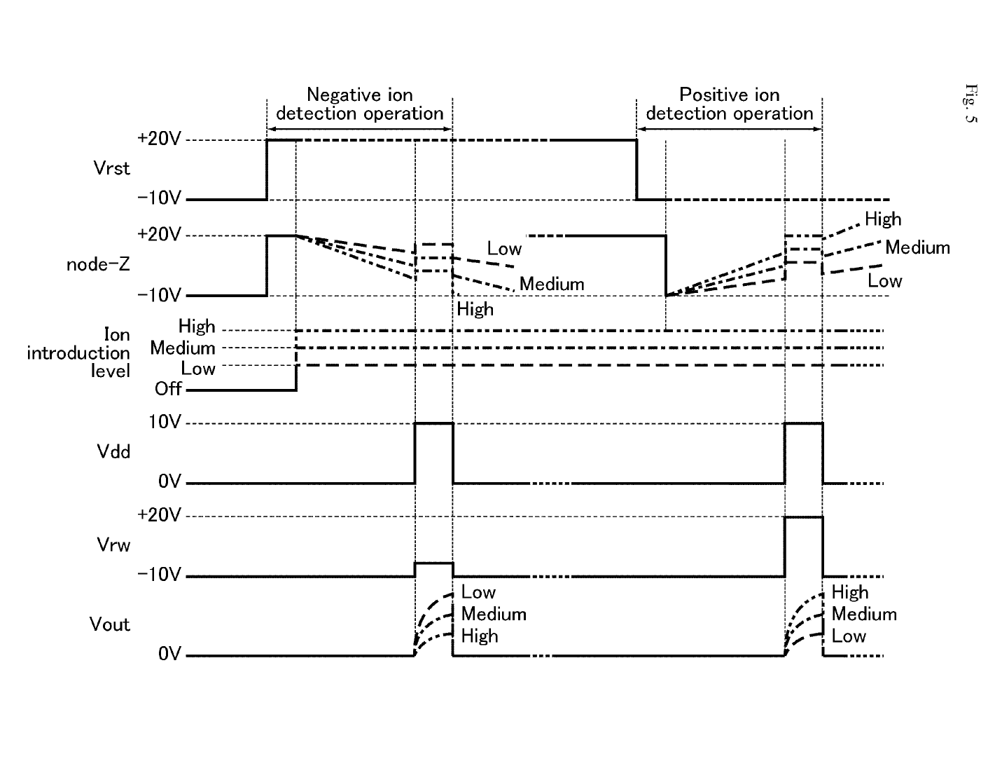

In the first conductive layer, an ion sensor antenna electrode 2a, a reset line 2b, a later-described connection line 22, a capacitor electrode 2c, and gate electrodes 2d and 2e are formed. These electrodes are formed in the first conductive layer, and can be formed by, for example, sputtering and photolithography from the same material through the same process. The first conductive layer is formed from a single or multiple metal layers. Specific examples of the first conductive layer include a single aluminum (Al) layer, a laminate of lower layer of Al/upper layer of titanium (Ti), and a laminate of lower layer of Al/upper layer of molybdenum (Mo). The reset line 2b, the connection line 22, and the capacitor electrode 2c are described below in more detail with reference to FIG. 4.

The insulating film 3 is formed on the substrate la in such a manner as to cover the ion sensor antenna electrode 2a, the reset line 2b, the connection line 22, the capacitor electrode 2c, and the gate electrodes 2d and 2e. On the insulating film 3, hydrogenated a-Si layers 4a and 4b, n+a-Si layers 5a and 5b, source electrodes 6a and 6b, drain electrodes 7a and 7b, and a capacitor electrode 8 are formed. The source electrodes 6a and 6b, the drain electrodes 7a and 7b, and the capacitor electrode 8 are formed in the second conductive layer, and can be formed by sputtering and photolithography from the same material through the same process. The second conductive layer is formed from a single or multiple metal layers. Specific examples of the second conductive layer include a single aluminum (Al) layer, a laminate of lower layer of Al/upper layer of Ti, and a laminate of lower layer of Ti/upper layer of Al. The hydrogenated a-Si layers 4a and 4b can be formed by, for example, chemical vapor deposition (CVD) and photolithography from the same material through the same process. The n+a-Si layers 5a and 5b can also be formed by, for example, CVD and photolithography from the same material through the same process. In this way, at least part of the materials and processes can be the same in forming the electrodes and semiconductors. The cost required in formation of the sensor TFT 30 and the pixel TFTs 40 including the electrodes and semiconductors therefore can be reduced. The components of the TFTs 30 and 40 are described in more detail later.

The passivation film 9 is formed on the insulating film 3 in such a manner as to cover the hydrogenated a-Si layers 4a and 4b, n+a-Si layers 5a and 5b, source electrodes 6a and 6b, drain electrodes 7a and 7b, and capacitor electrode 8. On the passivation film 9, a transparent conductive film 11a and a transparent conductive film 11b are formed. The transparent conductive film 11a is connected to the antenna electrode 2a via a contact hole 10a that penetrates the insulating film 3 and the passivation film 9. The transparent conductive film 11a is arranged to prevent the antenna electrode 2a from being exposed to the external environment because of the contact hole 10a. Hence, the arrangement makes it possible to prevent corrosion of the antenna electrode 2a as a result of being exposed to the external environment. The transparent conductive film 11b is connected to the drain electrode 7b via a contact hole 10b which penetrates the passivation film 9. These transparent electrodes 11a and 11b are formed in the third conductive layer, and can be formed by, for example, sputtering and photolithography from the same material through the same process. The third conductive layer is formed from a single or multiple transparent conducing films. Specific examples of the transparent conductive films include ITO films and IZO films. The materials constituting the transparent conductive films 11a and 11b are not required to be completely the same as each other. The processes for forming the transparent conductive films 11a and 11b are not required to be completely the same as each other either. For example, in the case that the transparent conductive film 11a and/or the transparent conductive film 11b have/has a multilayer structure, it is also possible to form only layer(s) common to the two transparent conductive films from the same material through the same process. Applying at least part of the materials and processes for forming the transparent conductive film 11b as described above to formation of the transparent conductive film 11a enables to form the transparent conductive film 11a at a low cost.

The light-shielding film 12a and the light-shielding film 12b can also be formed from the same material through the same process. Specifically, the light-shielding films 12a and 12b are formed from opaque metal (e.g. chromium (Cr)) films, opaque resin films, or other films. Examples of the resin films include acrylic resins containing carbon. Applying at least part of the materials and processes for forming the light-shielding film 12b as described above to formation of the light-shielding film 12a enables to form the light-shielding film 12a at a low cost.

The components of the TFTs 30 and 40 are described in more detail. The sensor TFT 30 is formed from the gate electrode 2d, the insulating film 3, the hydrogenated a-Si layer 4a, the n+a-Si layer 5a, the source electrode 6a, and the drain electrode 7a. The pixel TFTs 40 each are formed from the gate electrode 2e, the insulating film 3, the hydrogenated a-Si layer 4b, the n+a-Si layer 5b, the source electrode 6b, and the drain electrode 7b. The insulating film 3 functions as a gate insulating film in the sensor TFT 30 and the pixel TFTs 40. The TFTs 30 and 40 are bottom-gate TFTs. The n+a-Si layers 5a and 5b are doped with a V group element such as phosphorus (P). That is, the sensor TFT 30 and the pixel TFTs 40 are N-channel TFTs.

The antenna 41 includes the transparent conductive film 11a and the antenna electrode 2a. The capacitor electrodes 2c and 8 and the insulating film 3 configured to function as a dielectric form the capacitor 43 which is a capacitor. The capacitor electrode 2c is connected to the gate electrode 2d and the antenna electrode 2a. The capacitor electrode 8 is connected to a push-up/push-down line 23. Thereby, the capacitance of the gate electrode 2d and the antenna 41 can be increased, which enables to suppress the extraneous noise during the measurement of the ion concentration. Accordingly, more stable sensor operation and higher precision can be achieved. Also, both ions can be detected with high precision as described in detail later.

Next, the circuit configuration of the ion sensor circuit 107 and the TFT array 101 are described using FIG. 4. FIG. 4 is a view illustrating an equivalent circuit of portions of the ion sensor circuit 107 and the TFT array 101 according to the present embodiment.

First, the TFT array 101 is described. The gate electrodes 2d of the pixel TFTs 40 are connected to the gate driver 103 via the gate bus lines Gn, Gn+1, and so forth. The source electrodes 6b are connected to the source driver 104 via the source bus lines Sm, Sm+1, and so forth. The drain electrodes 7b of the pixel TFTs 40 are connected to the transparent conductive films lib which function as pixel electrodes. The pixel TFTs 40 are provided in the respective sub-pixels, and function as switching elements. The gate bus lines Gn, Gn+1, and so forth receive scanning pulses (scanning signals) in predetermined timings from the gate driver 103. The scanning pulses are applied to each pixel TFT 40 by a line sequential method. The source bus lines Sm, Sm+1, and so forth receive any image signals provided by the source driver 104 and/or display data calculated based on the negative ion concentration. Then, the image signals and/or display data are/is transmitted, in predetermined timing, to the pixel electrodes (transparent conductive films 11b) connected to the pixel TFTs 40 that are turned on for a certain period by inputted scanning pulses. The image signals and/or display data at a predetermined level written to the liquid crystals are stored for a certain period between the pixel electrodes having received these signals and/or data and the counter electrode (not illustrated) facing the pixel electrodes. Here, together with the liquid crystal capacitors formed between the pixel electrodes and the counter electrode, liquid crystal storage capacitors (Cs) 36 are formed. The liquid crystal storage capacitor 36 is formed between the drain electrode 7a and the liquid crystal auxiliary capacitor line Csn, Csn+1, or the like in the respective sub-pixels. The capacitor lines Csn, Csn+1, and so forth are formed in the first conductive layer, and are disposed in parallel with the gate lines Gn, Gn+1, and so forth.

Next, the circuit configuration of the ion sensor circuit 107 is described. The ion sensor circuit 107 detects both positive-charged ions and negative-charged ions. The drain electrode 7a of the sensor TFT 30 is connected to an input line 20. The input line 20 receives high voltage (+10 V) or low voltage (0 V). The voltage of the input line 20 is indicated by Vdd. The source electrode 6a is connected to an output line 21. The voltage of the output line 21 is indicated by Vout. The gate electrode 2d of the sensor TFT 30 is connected to the antenna 41 via the connection line 22. The connection line 22 is connected to the reset line 2b. The intersection (node) of the lines 22 and 2b is indicated by node-Z. The reset line 2b is a line for resetting the voltage of the node-Z, i.e., the voltage of the gate of the sensor TFT 30 and the antenna 41. The reset lines 2b receive high voltage (+20 V) or Low voltage (−20 V). The voltage of the reset line 2b is indicated by Vrst. The connection line 22 is connected to the push-up/push-down line 23 via the capacitor 43. The push-up/push-down line 23 receives high voltage or low voltage (for example, −10 V). The voltage of the push-up/push-down line 23 is indicated by Vrw. The high voltage and the low voltage for Vrw, i.e., the waveform of Vrw, can be adjusted to desired values by changing the values of the power supplies for supplying the respective high voltage and low voltage. Examples of the method of changing the value of the power supplies include the following methods (1) and (2).

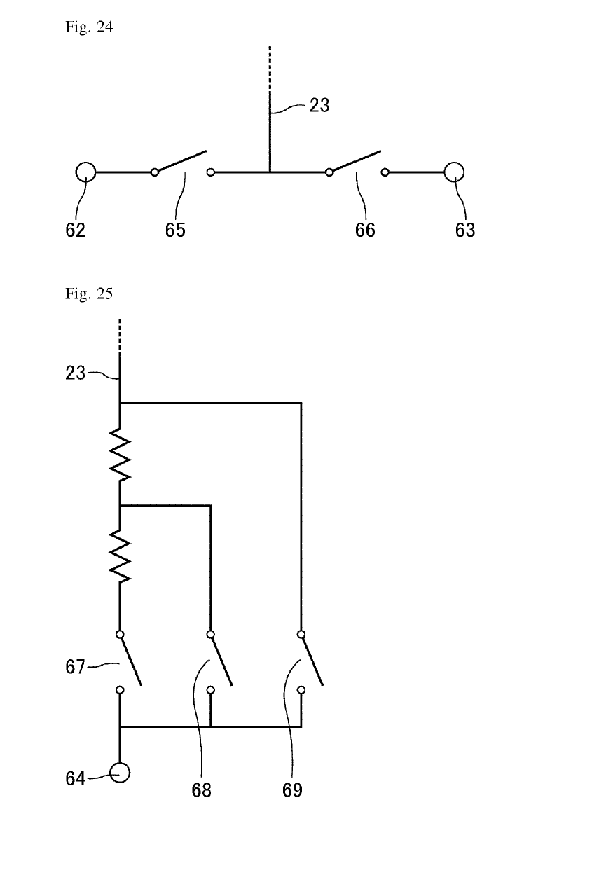

(1) The method of preparing multiple power supplies, and changing the power supply connected to the line 23 using a switch (e.g. semiconductor switch, transistor). Here, which power supply to connect, i.e., the connection destination of the switch, is controlled by signals from the host. More specifically, the method may be, as illustrated in FIG. 24, a method of preparing power supplies 62 and 63 having different power supply values, and switching the power supply connected to the line 23 using respective switches 65 and 66.

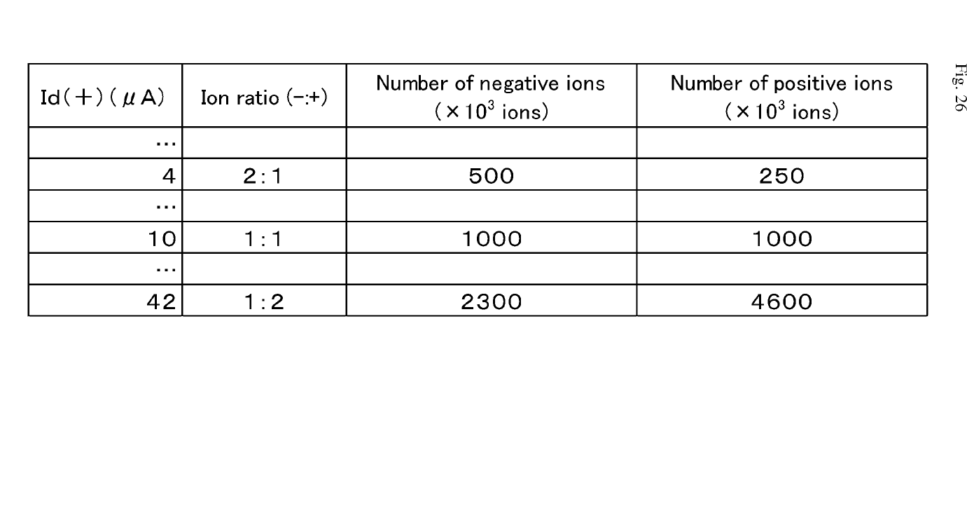

(2) The method of connecting a resistor ladder to one power supply, and selecting the voltage (resistance) to be output. Which voltage (resistance) to connect is controlled by signals from the host. More specifically, the method may be, as illustrated in FIG. 25, a method of connecting the power supply 64 to a resistor ladder, and selecting the desired voltage (resistance) to be output by turning on or off switches 67, 68, and 69.

The output line 21 is connected to a constant current circuit 25 and an analog-digital conversion circuit (ADC) 26. The constant current circuit 25 includes an N-channel TFT (constant current TFT), and the drain of the constant current TFT is connected to the output line 21. The source of the constant current TFT is connected to a constant current source, and the voltage Vss is fixed to a voltage lower than the high voltage for Vdd. The gate of the constant current TFT is connected to a constant-voltage source. The voltage Vbais of the gate of the constant current TFT is fixed to a predetermined value so that fixed electric current (for example, 1 μA) flows between the source and drain of the constant current TFT. The constant current circuit 25 and ADC 26 are formed within a driving/reading circuit 105.

The antenna electrode 2a, the gate electrode 2d, the reset line 2b, the capacitor electrode 2c, and the connection line 22 are integrally formed in the first conductive layer such that the antenna 41, the gate of the sensor TFT 30, the reset line 2b, the connection line 22, and the capacitor 43 are connected to each other. In contrast, the driving/reading circuit 105, the gate driver 103, and the source driver 104 each are not formed directly on the substrate la, but are formed on a semiconductor chip. The semiconductor chip is then mounted on the substrate 1a.

Next, the operational mechanism of the ion sensor circuit is described in detail using FIG. 5. FIG. 5 is a timing chart of an ion sensor circuit according to the present embodiment. As shown in FIG. 5, the ion sensor circuit 107 first detects negative ions, and thereafter detects positive ions. That is, the ion sensor circuit 107 alternatively performs driving to detect negative ions and driving to detect positive ions.

In the initial state, Vrst is set to a low voltage (−10 V). At this time, a power supply for applying a low voltage (−10 V) to the gate electrode 2e of the pixel TFT 40 can also be used as a power supply for setting Vrst to the low voltage (−10 V). Further, in the initial state, Vdd is set to a low voltage (0 V). Before starting measurement of an ion concentration, first, a high voltage (+20 V) is applied to the reset line 2b and the voltage of the antenna 41 (voltage of the node-Z) is reset to +20 V. At this time, a power supply for applying a high voltage (+20 V) to the gate electrode 2e of the pixel TFT 40 can also be used as a power supply for setting the reset line 2b to the high voltage (+20 V). After the voltage of the node-Z has been reset, the reset line 2b is held in a high impedance state. Subsequently, when an operation to detect negative ions is commenced and negative ions are collected by the antenna 41, the voltage of the node-Z that has been reset to +20 V, that is, charged to a positive voltage, is neutralized by the negative ions and decreases (sensing operation). The higher the negative ion concentration is, the faster the speed at which the voltage decreases. After a predetermined time period has elapsed since introduction of ions began, a high voltage (+10 V) is temporarily applied to the input line 20. That is, a pulse voltage of +10 V is applied to the input line 20. At the same time, an appropriate positive pulse voltage (high voltage) is applied to the push-up/push-down line 23 to push up the voltage of the node-Z through the capacitor 43. In addition, the output line 21 is connected to the constant current circuit 25. Accordingly, when a pulse voltage of +10 V is applied to the input line 20, a constant current flows in the input line 20 and the output line 21. However, a voltage Vout(−) of the output line 21 varies in accordance with the degree of opening of the gate of the sensor TFT 30, that is, the difference in the voltage of the node-Z that has been pushed up. The voltage Vout(−) is detected by the ADC 26 as a numerical value for calculating the ion concentration. In this connection, it is also possible to adopt a configuration in which the constant current circuit 25 is not provided, and a current Id(−) of the output line 21 that varies in accordance with the difference in the voltage of the node-Z is detected. The positive voltage that is applied to the push-up/push-down line 23 is set so that the potential of the gate enters a voltage region that is suitable for detecting negative ions with high accuracy. Hence, if the potential of the gate is in a voltage region that is suitable for detection of a negative ion concentration even without pushing up the voltage of the node-Z, it is not necessary to push up the voltage of the node-Z.

After detecting negative ions, a low voltage (−10 V) is then applied to the reset line 2b and the voltage of the antenna 41 (voltage of the node-Z) is reset to −10 V. At this time, a power supply for applying a low voltage (−10 V) to the gate electrode 2e of the pixel TFT 40 can also be used as a power supply for setting the reset line 2b to the low voltage (−10 V). After the voltage of the node-Z has been reset, the reset line 2b is held in a high impedance state. Subsequently, when an operation to detect positive ions is commenced and positive ions are collected by the antenna 41, the voltage of the node-Z that has been reset to −10 V, that is, charged to a negative voltage, is neutralized by the positive ions and increases (sensing operation). The higher the positive ion concentration is, the faster the speed at which the voltage increases. After a predetermined time period has elapsed since introduction of ions began, a high voltage (+10 V) is temporarily applied to the input line 20. That is, a pulse voltage of +10 V is applied to the input line 20. At the same time, an appropriate positive pulse voltage (high voltage) is applied to the push-up/push-down line 23 to push up the voltage of the node-Z through the capacitor 43. In addition, the output line 21 is connected to the constant current circuit 25. Accordingly, when the pulse voltage of +10 V is applied to the input line 20, a constant current flows in the input line 20 and the output line 21. However, a voltage Vout(+) of the output line 21 varies in accordance with the degree of opening of the gate of the sensor TFT 30, that is, the difference in the voltage of the node-Z that has been pushed up. The voltage Vout(+) is detected by the ADC 26 as a numerical value for calculating the ion concentration. In this connection, it is also possible to adopt a configuration in which the constant current circuit 25 is not provided and a current Id(+) of the output line 21 that varies in accordance with the difference in the voltage of the node-Z is detected. A positive voltage that is applied to the push-up/push-down line 23 is set so that the potential of the gate enters a voltage region that is suitable for detecting positive ions with high accuracy.

Note that depending on the ratio between both ions, Vout (or Id) may become 0 or conversely may become an extremely high value. At such time, an appropriate value for Vout (or Id) can be obtained by adjusting the time period t from when ions are introduced until Vout (or Id) is detected.

A time period (interval) between detecting negative ions and detecting positive ions, that is, a time period from after a read operation for negative ion detection (application of a pulse to Vrw) until a reset operation for positive ion detection (application of −10 V to Vrst) is as described in the following (1) and (2). (1) In a case where ions are continuously introduced, that is, a case where ion introduction is not stopped when switching between a negative ion detection operation and a positive ion detection operation, it is sufficient to provide an interval of a time period until the Vrw line and the Vout line after a read operation reach a predetermined potential (−10 V and 0 V, respectively, in the timing chart shown in FIG. 5), and more specifically it is sufficient to provide a time period of 10 microseconds or more. (2) In a case where ion introduction is stopped when switching between a negative ion detection operation and a positive ion detection operation, because time is required until the ion concentration stabilizes, a longer time period than in the foregoing (1) is required.

According to the present embodiment, a high voltage of Vdd is not particularly limited to +10 V, and the high voltage of Vdd may be the same as a high voltage applied to the reset line 2b, that is, the same as the high voltage of +20 V that is applied to the gate electrode 2e of the pixel TFT 40. Thus, a power supply for applying the high voltage to the gate electrode 2e of the pixel TFT 40 can also be used as a power supply for applying the high voltage of Vdd. Further, a voltage (low voltage of Vrw) of the push-up/push-down line 23 in a state where the voltage of the node-Z is not pushed up may be −10 V, which is the same as the low voltage applied to the gate electrode 2e of the pixel TFT 40. Thus, a power supply for applying the low voltage to the gate electrode 2e of the pixel TFT 40 can also be used as a power supply for applying the low voltage of Vrw.

Thus, according to Embodiment 1, with respect to a sample in which both ions are mixed, it is possible to calculate an ion concentration simply and with high accuracy using detection results for positive ions and negative ions. Note that the calculation method is common among the respective embodiments and is described in detail in Embodiment 3.

Further, according to Embodiment 1, since it is possible to detect both ions using the single sensor TFT 30, miniaturization of the device and a reduction in manufacturing costs are enabled.

Although the N-channel sensor TFT 30 and pixel TFT 40 are used according to Embodiment 1, P-channel TFTs may also be used.

Further, the order of detecting negative ions and positive ions is not particularly limited, and negative ions may be detected in a consecutive manner after detecting positive ions.

### Embodiment 2

A display device according to Embodiment 2 has the same configuration as Embodiment 1, except for the following points. That is, an ion sensor circuit 207 of Embodiment 2 includes a negative ion-detecting sensor circuit 201 and a positive ion-detecting sensor circuit 202. The negative ion-detecting sensor circuit 201 includes the N-channel sensor TFT 30 and the antenna 41 described in Embodiment 1. The positive ion-detecting sensor circuit 202 includes a P-channel sensor TFT 30b and an antenna 41b.

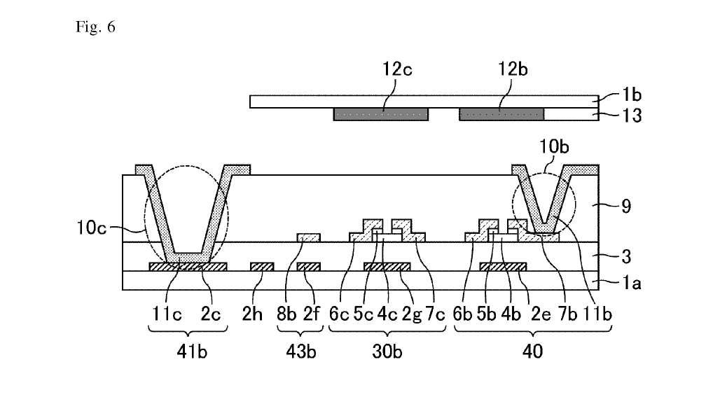

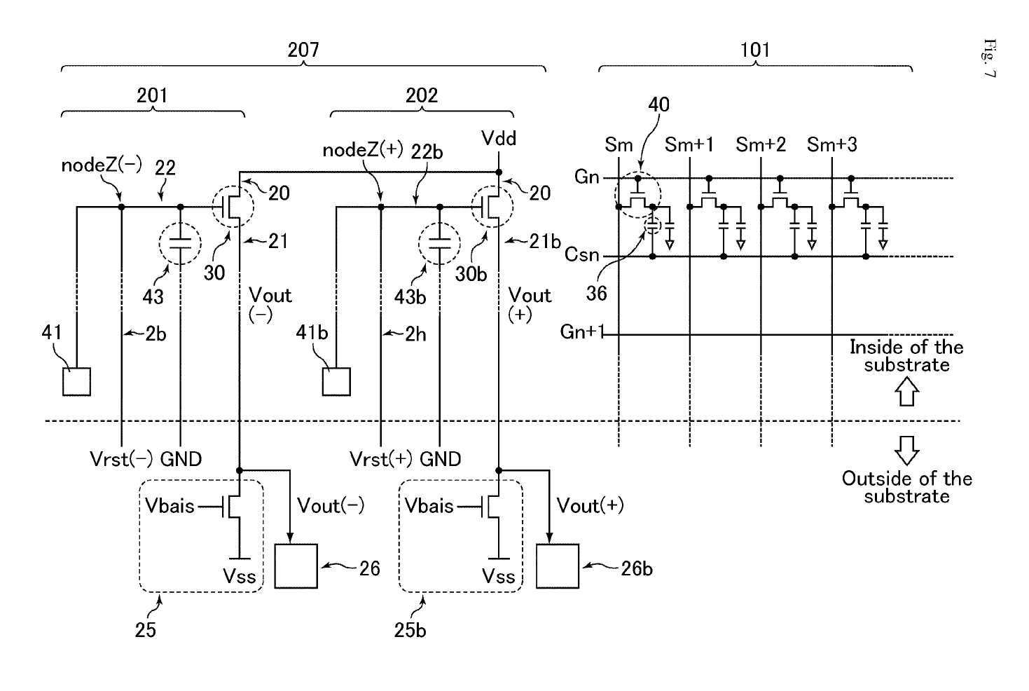

The configuration of the positive ion-detecting sensor circuit 202 will now be described in detail using FIG. 6. FIG. 6 is a schematic cross-sectional view of the ion sensor and the display device according to the present embodiment, and includes one portion of the positive ion-detecting sensor circuit. A description of common components with respect to the display device according to Embodiment 1 is omitted here.

As shown in FIG. 6, the sensor circuit 202 is an ion sensor element and includes the sensor TFT 30b and the ion sensor antenna 41b.

The antenna 41b is a conductive member that detects (collects) ions in air, and is connected to a gate of the sensor TFT 30b. When ions adhere to the surface of the antenna 41b, the potential of the antenna 41b changes, and the potential of the gate of the sensor TFT 30b also changes in accordance therewith. As a result, a current and/or voltage between the source and drain of the sensor TFT 30b changes.

The sensor TFT 30b is provided on a main surface on a liquid crystal side of the substrate 1a (TFT array substrate) at a position at which the substrates 1a and 1b face each other. The antenna 41b is provided outside a channel region of the sensor TFT 30. The sensor TFT 30b and a light-shielding film 12c that faces the sensor TFT 30b are provided at an edge part (picture-frame region) of the display 130.

According to the present embodiment, at least the sensor TFT 30 and the ion sensor antenna 41 that are included in the sensor circuit 201, the sensor TFT 30b and the ion sensor antenna 41b that are included in the sensor circuit 202, and the TFT array 101 of the display-driving circuit are formed on the substrate 1a.

The light-shielding film 12c is provided on a main surface on a liquid crystal side of the substrate 1b (opposed substrate) at a position at which the substrates 1a and 1b face each other. The light-shielding film 12c is provided at a position that faces the sensor TFT 30b. The sensor TFT 30b includes a-Si that is a semiconductor whose properties with respect to light vary, which will be described in detail later. As described above, because the sensor TFT 30b is shielded from light by the light-shielding film 12c, variations in the properties of a-Si, that is, in the output properties of the sensor TFT 30b can be suppressed, and hence an ion concentration can be measured with higher accuracy.

An ion sensor antenna electrode 2c, reset line 2h, connection line 22b that is described later, a capacitor electrode 2f and a gate electrode 2g are formed in the first conductive layer of the sensor circuit 202. The reset line 2h, connection line 22b and capacitor electrode 2f are described in detail later using FIG. 7.

In the sensor circuit 202, hydrogenated a-Si layers 4c and 4b, an n+a-Si layer 5c, a source electrode 6c, a drain electrode 7c and a capacitor electrode 8b are formed on the insulating film 3. The source electrode 6c, drain electrode 7c and capacitor electrode 8b are formed in the second conductive layer.

In the sensor circuit 202, the passivation film 9 is provided on the insulating film 3 so as to cover the hydrogenated a-Si layer 4c, the n+a-Si layer 5c, the source electrode 6c, the drain electrode 7c and the capacitor electrode 8b.

In the sensor circuit 202, a transparent conductive film 11c is formed on the passivation film 9. The transparent conductive film 11c is connected to the antenna electrode 2c through a contact hole 10c that penetrates through the insulating film 3 and the passivation film 9. By providing the transparent conductive film 11c so that the antenna electrode 2c is not exposed by the contact hole 10c, the antenna electrode 2c can be prevented from being exposed to the external environment and corroding. The transparent conductive film 11c is formed in the third conductive layer.

The light-shielding film 12c is formed from an opaque metal film such as chrome (Cr) or an opaque resin film or the like. An acrylic resin including carbon may be mentioned as an example of the resin film.

The constituent elements of the TFT 30b will now be described in further detail. The sensor TFT 30b is formed from the gate electrode 2g, the insulating film 3, the hydrogenated a-Si layer 4c, the n+a-Si layer 5c, the source electrode 6c and the drain electrode 7c. The insulating film 3 functions as a gate insulator in the sensor TFT 30b. The TFT 30b is a bottom-gate TFT. The p+a-Si layer 5c is doped with a third group element such as boron (B). That is, the sensor TFT 30b is a P-channel TFT.

The antenna 41b is formed from the transparent conductive film 11c and the antenna electrode 2c. A capacitor 43b is formed from the capacitor electrodes 2f and 8b and the insulating film 3 that functions as a dielectric. The capacitor electrode 2f is connected to the gate electrode 2g and the antenna electrode 2c, and the capacitor electrode 8b is grounded. Since it is possible to increase the capacitance of the gate electrode 2g and antenna 41b by providing the capacitor 43b, the influence of external noise during measurement of an ion concentration can be suppressed. Accordingly, the sensor operations can be made more stable and the accuracy can be further increased. Similarly, according to the present embodiment, the capacitor electrode 8 of the capacitor 43 of the sensor circuit 201 is grounded and is not connected to the push-up/push-down line 23.

The circuit configuration of the ion sensor circuit 207 according to the present embodiment will now be described using FIG. 7. FIG. 7 is an equivalent circuit that illustrates the ion sensor circuit 207 and one part of the TFT array 101 according to the present embodiment. The display device according to the present embodiment has the same TFT array 101 as Embodiment 1, and hence a description thereof is omitted here.

The ion sensor circuit 207 includes the negative ion-detecting sensor circuit 201 and the positive ion-detecting sensor circuit 202.

First, the negative ion-detecting sensor circuit 201 will be described. The sensor circuit 201 has the same configuration as the ion sensor circuit 107 except that the connection line 22 is connected to a ground (GND) through the capacitor 43. A high voltage (+10 V) or a low voltage (0 V) is applied to the input line 20, and the voltage of the input line 20 is taken as Vdd. The voltage of the output line 21 is taken as Vout(−). A point of intersection (node) between the lines 22 and 2b is taken as a node-Z(−). A high voltage (+20 V) or a low voltage (−10 V) is applied to the reset line 2b, and the voltage of the reset line 2b is taken as Vrst(−).

Next, the positive ion-detecting sensor circuit 202 is described. The input line 20 is connected to the drain electrode 7c of the sensor TFT 30b. The output line 21b is connected to the source electrode 6c. The voltage of the output line 21b is taken as Vout(+). The antenna 41b is connected through the connection line 22b to the gate electrode 2g of the sensor TFT 30b. Further, the reset line 2h is connected to the connection line 22b. A point of intersection (node) between the lines 22b and 2h is taken as a node-Z(+). The reset line 2h is a line for resetting the node-Z(+), that is, a voltage between the gate of the sensor TFT 30b and the antenna 41b. A high voltage (+20 V) or a low voltage (−10 V) is applied to the reset line 2h, and the voltage of the reset line 2h is taken as Vrst(+). A ground (GND) is connected through the capacitor 43b to the connection line 22b. A constant current circuit 25b and an analog-digital conversion circuit (ADC) 26b are connected to the output line 21b. The configuration of the constant current circuit 25b is the same as the configuration of the constant current circuit 25, and hence a detailed description thereof is omitted here.

Note that, because the antenna electrode 2c, the gate electrode 2g, the reset line 2h, the capacitor electrode 2f and the connection line 22b are integrally formed in the first conductive layer, the antenna 41b, the gate of the sensor TFT 30b, the reset line 2h, the connection line 22b and the capacitor 43b are connected to each other.

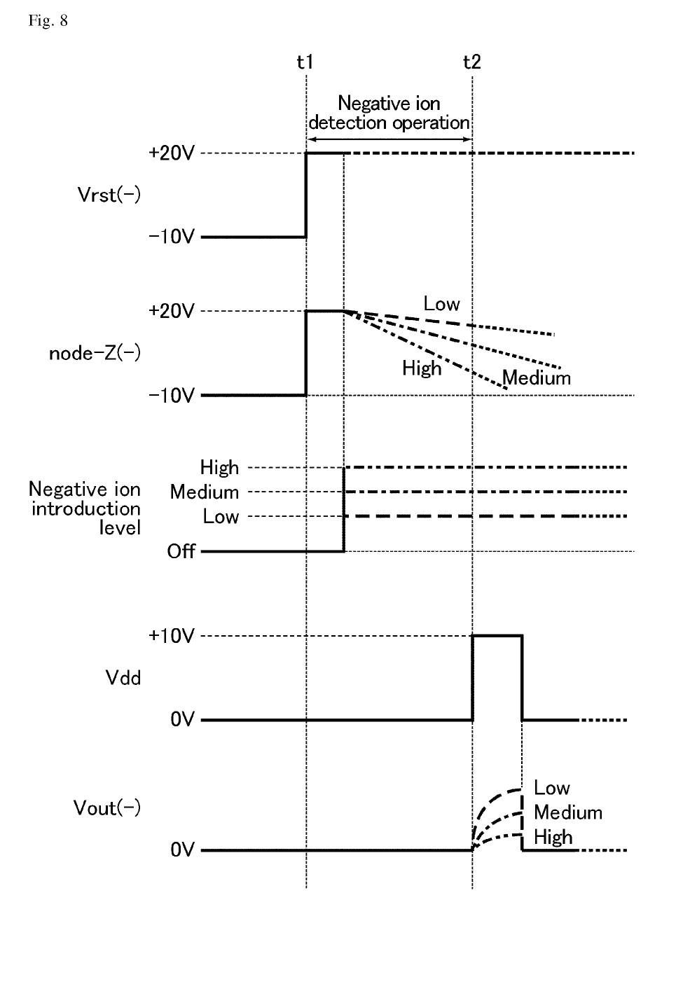

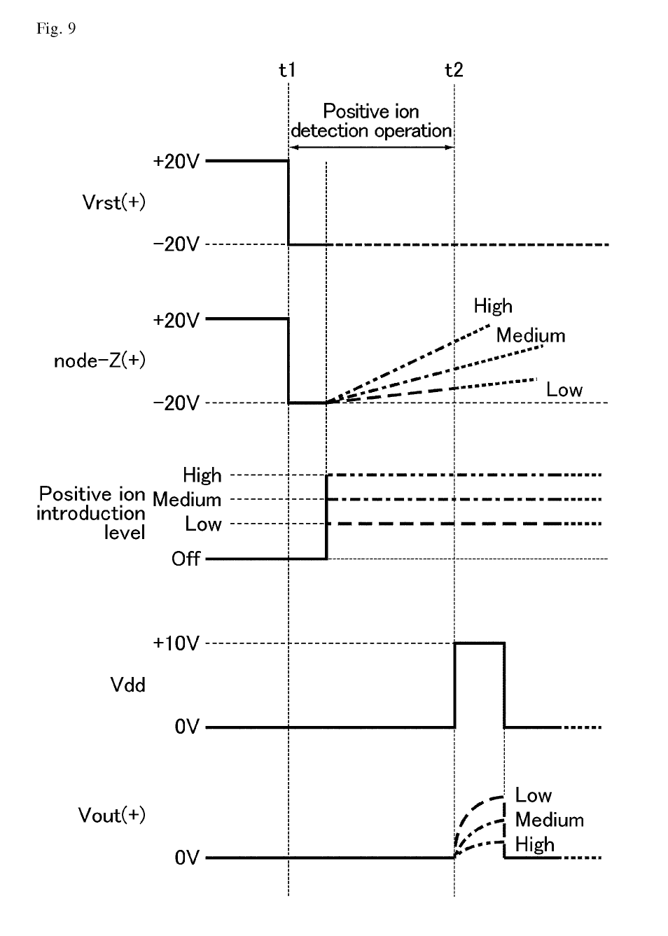

Next, the operational mechanism of the ion sensor circuit will be described in detail using FIG. 8 and FIG. 9. FIG. 8 is a timing chart of the negative ion-detecting sensor circuit according to the present embodiment. FIG. 9 is a timing chart of the positive ion-detecting sensor circuit according to the present embodiment. As shown in FIGS. 8 and 9, the ion sensor circuit 207 performs detection of negative ions using the negative ion-detecting sensor circuit 201 and detection of positive ions using the positive ion-detecting sensor circuit 202 at the same time. First, detection of negative ions will be described.

In the initial state, Vrst(−) is set to a low voltage (−10 V). At this time, a power supply for applying a low voltage (−10 V) to the gate electrode 2e of the pixel TFT 40 can be also used as a power supply for setting Vrst(−) to the low voltage (−10 V). Further, in the initial state, Vdd is set to a low voltage (0 V). Before starting measurement of an ion concentration, at a time t1, first a high voltage (+20 V) is applied to the reset line 2b and the voltage of the antenna 41 (voltage of the node-Z(−)) is reset to +20 V. At this time, a power supply for applying a high voltage (+20 V) to the gate electrode 2e of the pixel TFT 40 can also be used as a power supply for applying Vrst(−). After the voltage of the node-Z(−) has been'reset, the reset line 2b is held in a high impedance state. Subsequently, when an operation to introduce ions is commenced and negative ions are collected by the antenna 41, the voltage of the node-Z(−) that has been reset to +20 V, that is, charged to a positive voltage, is neutralized by the negative ions and decreases (sensing operation). The higher the negative ion concentration is, the faster the speed at which the voltage decreases. At a time t2 that is after a predetermined time period has elapsed since introduction of ions began, a high voltage (+10 V) is temporarily applied to the input line 20. That is, a pulse voltage of +10 V is applied to the input line 20. Further, the output line 21 is connected to the constant current circuit 25. Accordingly, when a pulse voltage of +10 V is applied to the input line 20, a constant current flows in the input line 20 and the output line 21. However, the voltage Vout(−) of the output line 21 varies in accordance with the degree of opening of the gate of the sensor TFT 30, that is, a difference in the voltage of the node-Z(−). The voltage Vout(−) is detected with the ADC 26 as a numerical value for calculating the ion concentration. In this connection, it is also possible to adopt a configuration in which the constant current circuit 25 is not provided, and a current Id(−) of the output line 21 that varies in accordance with a difference in the voltage of the node-Z(−) is detected.

Next, detection of positive ions will be described.

In the initial state, Vrst(+) is set to a high voltage (+20 V). At this time, a power supply for applying a high voltage (+20 V) to the gate electrode 2e of the pixel TFT 40 can also be used as a power supply for setting Vrst(+) to the high voltage (+20 V). Further, in the initial state, Vdd is set to a low voltage (0 V). Before starting measurement of an ion concentration, at a time t1, first a low voltage (−20 V) is applied to the reset line 2h and the voltage of the antenna 41b (voltage of the node-Z(+)) is reset to −20 V. After the voltage of the node-Z(+) has been reset, the reset line 2h is held in a high impedance state. Subsequently, when an operation to introduce ions is commenced and positive ions are collected by the antenna 41b, the voltage of the node-Z(+) that has been reset to −20 V, that is, charged to a negative voltage, is neutralized by the positive ions and increases (sensing operation). The higher the positive ion concentration is, the faster the speed at which the voltage increases. At a time t2 that is after a predetermined time period has elapsed since introduction of ions began, a high voltage (+10 V) is temporarily applied to the input line 20. That is, a pulse voltage of +10 V is applied to the input line 20. Further, the output line 21b is connected to the constant current circuit 25b. Accordingly, when a pulse voltage of +10 V is applied to the input line 20, a constant current flows in the input line 20 and the output line 21b. However, the voltage Vout(+) of the output line 21b varies in accordance with the degree of opening of the gate of the sensor TFT 30b, that is, a difference in the voltage of the node-Z(+). The voltage Vout(+) is detected with the ADC 26b as a numerical value for calculating the ion concentration. In this connection, it is also possible to adopt a configuration in which the constant current circuit 25b is not provided, and a current Id(+) of the output line 21b that varies in accordance with a difference in the voltage of the node-Z(+) is detected.

According to the present embodiment, the high voltage of Vdd is not particularly limited to +10 V, and the high voltage of Vdd may be the same as the high voltage applied to the reset line 2b and 2h, that is, the same as the high voltage of +20 V that is applied to the gate electrode 2e of the pixel TFT 40. Thus, a power supply for applying a high voltage to the gate electrode 2e of the pixel TFT 40 can also be used as a power supply for applying the high voltage of Vdd.

Further, according to the present embodiment, the low voltage that is applied to the reset line 2h is not particularly limited to −20 V, and the low voltage applied to the reset line 2h may be −10 V that is the same as the low voltage applied to the gate electrode 2e of the pixel TFT 40. Thus, a power supply for applying a low voltage to the gate electrode 2e of the pixel TFT 40 can used be also as a power supply for applying a low voltage to be applied to the reset line 2h.

Thus, according to Embodiment 2, with respect to a sample in which both ions are mixed, it is possible to calculate an ion concentration simply and with high accuracy using detection results for positive ions and negative ions. Note that the calculation method is described in detail in Embodiment 3.

Further, according to Embodiment 2, since it is possible to measure both ions at the same time, an ion concentration can be measured with higher accuracy in comparison to Embodiment 1 in which one of the negative and positive ions is measured first, and thereafter the other of the negative and positive ions is measured.

### Embodiment 3

A display device according to Embodiment 3 has the same configuration as that of Embodiment 2 except for the following points. That is, an ion sensor circuit 307 of Embodiment 3 includes a negative ion-detecting sensor circuit 301 and a positive ion-detecting sensor circuit 302, and the sensor circuits 301 and 302 each include a push-up/push-down line. The sensor circuit 302 includes an N-channel sensor TFT 30c instead of the P-channel sensor TFT 30b.

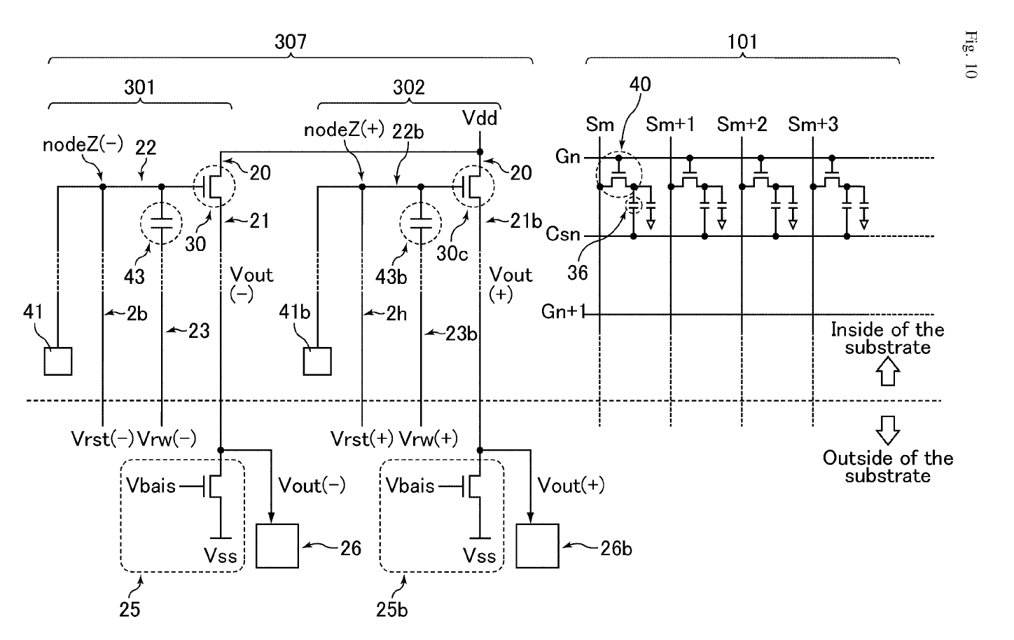

The circuit configuration of the ion sensor circuit 307 according to the present embodiment will now be described using FIG. 10. FIG. 10 is an equivalent circuit that illustrates the ion sensor circuit 307 and one part of the TFT array 101 according to the present embodiment. The display device according to the present embodiment has the same TFT array 101 as Embodiment 1, and hence a description thereof is omitted here.

The ion sensor circuit 307 includes the negative ion-detecting sensor circuit 301 and the positive ion-detecting sensor circuit 302.

First, the negative ion-detecting sensor circuit 301 will be described. The sensor circuit 301 has the same configuration as the ion sensor circuit 107. A high voltage (+10 V) or a low voltage (0 V) is applied to the input line 20, and the voltage of the input line 20 is taken as Vdd. The voltage of output line 21a is taken as Vout(−). A point of intersection (node) between the lines 22a and 2b is taken as a node-Z(−). A high voltage (+20 V) or a low voltage (−10 V) is applied to the reset line 2b, and the voltage of the reset line 2b is taken as Vrst(−). A high voltage or low voltage (for example, −10 V) is applied to the push-up/push-down line 23, and the voltage of the push-up/push-down line 23 is taken as Vrw(−). The high voltage of Vrw(−) can be adjusted to a desired value. Note that the method for changing the value of the power supply described in Embodiment 1 can be used as a method for adjusting the high voltage of Vrw(−) to a desired value.

Next, the positive ion-detecting sensor circuit 302 will be described. The sensor circuit 302 has the same configuration as the sensor circuit 202 except that the connection line 22b is connected to a push-up/push-down line 23b through the capacitor 43b and that the sensor circuit 302 includes the N-channel sensor TFT 30c instead of the P-channel sensor TFT 30b. The voltage of the output line 21b is taken as Vout(+). A point of intersection (node) between the lines 22b and 2h is taken as a node-Z(+). A high voltage (+20 V) or a low voltage (−10 V) is applied to the reset line 2h, and the voltage of the reset line 2h is taken as Vrst(+). A high voltage or a low voltage (for example, −10 V) is applied to the push-up/push-down line 23b, and the voltage of the push-up/push-down line 23b is taken as Vrw(+). The high voltage of Vrw(+) can be adjusted to a desired value.

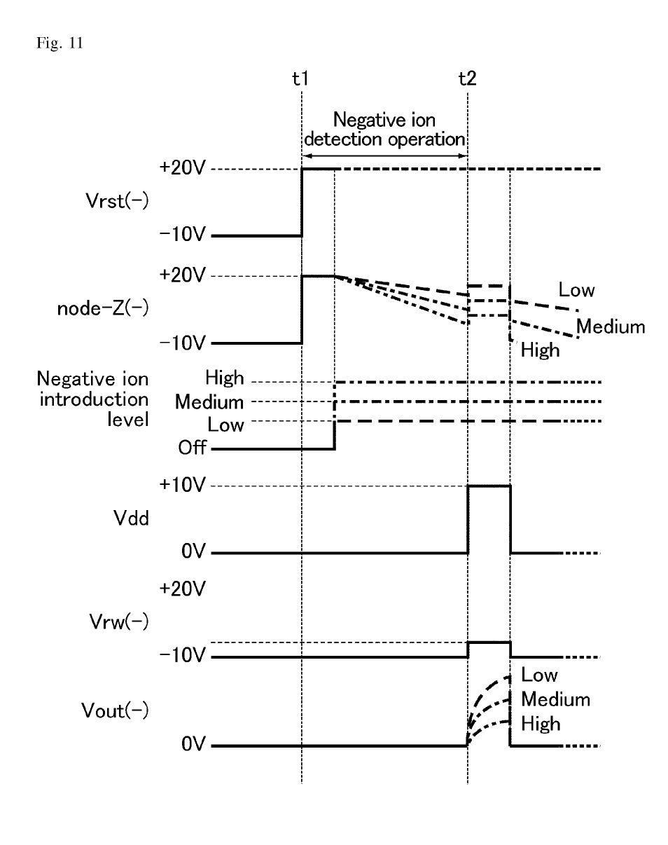

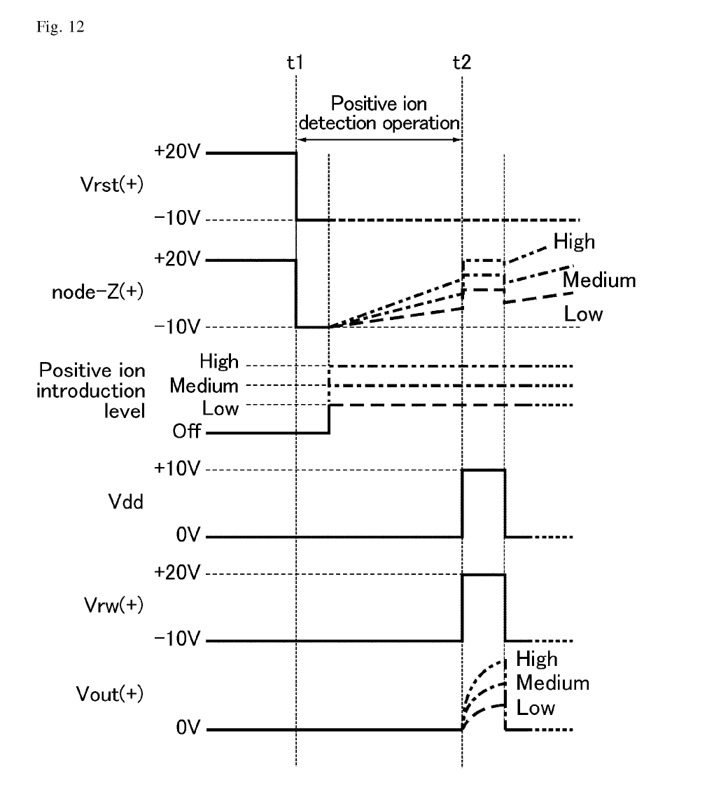

Next, the operational mechanism of the ion sensor circuit will be described in detail using FIG. 11 and FIG. 12. FIG. 11 is a timing chart of the negative ion-detecting sensor circuit according to the present embodiment. FIG. 12 is a timing chart of the positive ion-detecting sensor circuit according to the present embodiment. As shown in FIGS. 11 and 12, the ion sensor circuit 307 performs detection of negative ions using the negative ion-detecting sensor circuit 301 and detection of positive ions using the positive ion-detecting sensor circuit 302 at the same time. First, detection of negative ions will be described.

In the initial state, Vrst(−) is set to a low voltage (−10 V). At this time, a power supply for applying a low voltage (−10 V) to the gate electrode 2e of the pixel TFT 40 can also be used as the power supply for setting Vrst(−) to the low voltage (−10 V). Further, in the initial state, Vdd is set to a low voltage (0 V). Before starting measurement of an ion concentration, at a time t1, first a high voltage (+20 V) is applied to the reset line 2b and the voltage of the antenna 41 (voltage of the node-Z(−)) is reset to +20 V. At this time, a power supply for applying a high voltage (+20 V) to the gate electrode 2e of the pixel TFT 40 can also be used as the power supply for setting the high voltage (+20 V) in the reset line 2b. After the voltage of the node-Z(−) has been reset, the reset line 2b is held in a high impedance state. Subsequently, when an operation to introduce ions is commenced and negative ions are collected by the antenna 41, voltage of the node-Z(−) that has been reset to +20 V, that is, charged to a positive voltage, is neutralized by the negative ions and decreases (sensing operation). The higher the negative ion concentration is, the faster the speed at which the voltage decreases. At a time t2 that is after a predetermined time period has elapsed since introduction of ions began, a high voltage (+10 V) is temporarily applied to the input line 20. That is, a pulse voltage of +10 V is applied to the input line 20. At the same time, an appropriate positive pulse voltage (high voltage) is applied to the push-up/push-down line 23 to push up the voltage of the node-Z(−) through the capacitor 43. Further, the output line 21 is connected to the constant current circuit 25. Accordingly, when a pulse voltage of +10 V is applied to the input line 20, a constant current flows in the input line 20 and the output line 21. However, a voltage Vout(−) of the output line 21 varies in accordance with the degree of opening of the gate of the sensor TFT 30, that is, a difference in the voltage of the node-Z(−) that has been pushed up. The voltage Vout(−) is detected with the ADC 26 as a numerical value for calculating the ion concentration. In this connection, it is also possible to adopt a configuration in which the constant current circuit 25 is not provided, and a current Id(−) of the output line 21 that varies in accordance with a difference in the voltage of the node-Z(−) is detected. A positive voltage that is applied to the push-up/push-down line 23 is set in a voltage region of the gate that is suitable for detecting negative ions with high accuracy. Hence, if the potential of the gate is in a voltage region that is suitable for detection of a negative ion concentration even without pushing up the voltage of the node-Z(−), it is not necessary to push up the voltage of the node-Z(−).

Next, detection of positive ions will be described.

In the initial state, Vrst(+) is set to a high voltage (+20 V). At this time, a power supply for applying a high voltage (+20 V) to the gate electrode 2e of the pixel TFT 40 can also be used as a power supply for setting Vrst(+) to the high voltage (+20 V). Further, in the initial state, Vdd is set to a low voltage (0 V). Before starting measurement of an ion concentration, at a time t1, first a low voltage (−10 V) is applied to the reset line 2h and the voltage of the antenna 41b (voltage of the node-Z) is reset to −10 V. At this time, a power supply for applying a low voltage (−10 V) to the gate electrode 2e of the pixel TFT 40 can also be used as a power supply for setting the low voltage (-10 V) in the reset line 2h. After the voltage of the node-Z(+) has been reset, the reset line 2h is held in a high impedance state. Subsequently, when an operation to introduce ions is commenced and positive ions are collected by the antenna 41b, the voltage of the node-Z(+) that has been reset to −10 V, that is, charged to a negative voltage, is neutralized by the positive ions and increases (sensing operation). The higher the positive ion concentration is, the faster the speed at which the voltage increases. At a time t2 that is after a predetermined time period has elapsed since introduction of ions began, a high voltage (+10 V) is temporarily applied to the input line 20. That is, a pulse voltage of +10 V is applied to the input line 20. At the same time, an appropriate positive pulse voltage (high voltage) is applied to the push-up/push-down line 23b to push up the voltage of the node-Z(+) through the capacitor 43b. Further, the output line 21b is connected to the constant current circuit 25b. Accordingly, when a pulse voltage of +10 V is applied to the input line 20, a constant current flows in the input line 20 and the output line 21b. However, a voltage Vout(+) of the output line 21b varies in accordance with the degree of opening of the gate of the sensor TFT 30c, that is, a difference in the voltage of the node-Z(+) that has been pushed up. The voltage Vout(+) is detected with the ADC 26b as a numerical value for calculating the ion concentration. In this connection, it is also possible to adopt a configuration in which the constant current circuit 25b is not provided, and a current Id(+) of the output line 21b that varies in accordance with a difference in the voltage of the node-Z(+) is detected. A positive voltage that is applied to the push-up/push-down line 23b is set in a voltage region of the gate that is suitable for detecting positive ions with high accuracy.

Next, the method for calculating an ion concentration is described. Note that, hereinafter, for example, a fact that a ratio of a negative ion concentration to a positive ion concentration=X:Y is also referred to as “the ion ratio is X:Y”.

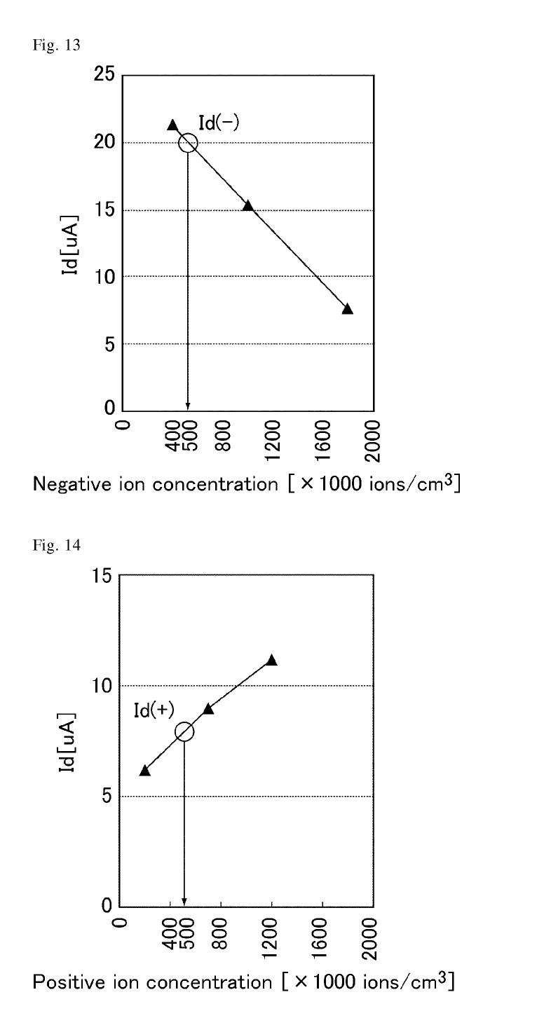

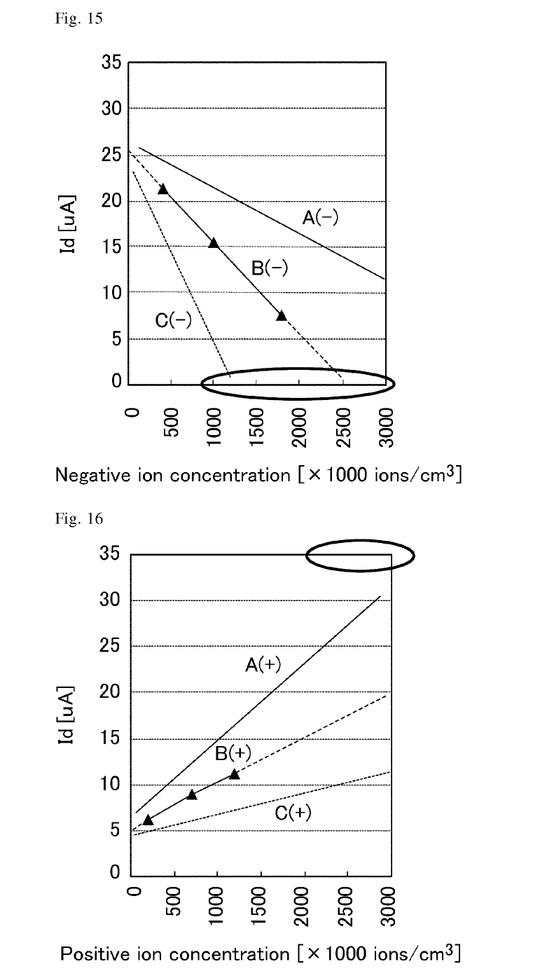

FIG. 13 and FIG. 15 illustrate examples of curves (calibration curves) that show a relation between Id(−) and a negative ion concentration. FIG. 14 and FIG. 16 illustrate examples of curves (calibration curves) that show a relation between Id(+) and a positive ion concentration. These calibration curves were prepared by using the ion sensor of the present embodiment to measure samples that included approximately equal proportions of positive ions and negative ions of known concentrations and plotting the relation between the ion concentrations and Id(−) or Id(+). Further, Id(−) and Id(+) in the respective figures are outputs after a time period t (time period from the time t1 to the time t2) has elapsed from the start of ion detection.

Note that 4 μm was adopted as the channel length of each of the sensor TFTs 30 and 30c, and 100 μm was adopted as the channel widths of each of the sensor TFTs 30 and 30c. A voltage of +10 V was adopted as the high voltage of Vdd. A voltage of +20 V was adopted as the high voltage of Vrst(−). A voltage of −20 V was adopted as the low voltage of Vrst(+). A capacitance of 10 pF was adopted as the capacitance of each of the capacitors 43 and 43b. A pulse voltage with a low voltage of −10 V and a high voltage of +20 V was adopted as Vrw(−). A pulse voltage with a low voltage of −10 V and a high voltage of +20 V was also adopted as Vrw(+). An area of 4000 μm×4000 μm was adopted as the area of each of the antennas 41 and 41b.

As a result, in the examples shown in FIG. 13 and FIG. 14, it was found that when Id(−) and Id(+) are present on the calibration curve of FIG. 13 and the calibration curve of FIG. 14, respectively, a positive ion concentration and a negative ion concentration were, for example, 500³ ions/cm³ and 500³ ions/cm³, respectively.

That is, as shown in FIG. 15 and FIG. 16, by obtaining at least two calibration curves for each of Id(−) and Id(+), a concentration ratio between both ions can be estimated by comparing a combination of values for Id(−) and Id(+) that are obtained from a sensor circuit and the respective calibration curves, and as a result the concentrations of both ions can be determined.

FIG. 15 shows a calibration curve A(−) for a case where a negative ion concentration<positive ion concentration (for example, the ion ratio=1:2), a calibration curve B(−) for a case where a negative ion concentration=positive ion concentration (the ion ratio=1:1), and a calibration curve C(−) for a case where a negative ion concentration>positive ion concentration (for example, the ion ratio=2:1). FIG. 16 shows a calibration curve A(+) for a case where a negative ion concentration<positive ion concentration (for example, the ion ratio=1:2), a calibration curve B(+) for a case where a negative ion concentration=positive ion concentration (the ion ratio=1:1), and a calibration curve C(+) for a case where a negative ion concentration>positive ion concentration (for example, the ion ratio=2:1).

As shown by an ellipse in FIG. 15 and FIG. 16, depending on the ion concentration ratio, there are cases where the output Id is 0 or is saturated. In such cases it is sufficient to change the time period t for measuring Id(−) and Id(+).

In addition, since it is unrealistic to acquire calibration curves for all combinations of Id(−) and Id(+) in advance, it is preferable to determine Id values between one calibration curve and another calibration curve by computation (complementation). It is thereby possible to reduce the size of a memory (unshown) and simplify the memory task.

In this connection, the reason for computationally determining Id values between one calibration curve and another calibration curve is as follows. As is apparent from the measurement result graphs shown in FIGS. 13 to 16, each calibration curve is a linear expression, and therefore if the ion concentration ratio changes, the gradient of the calibration curve will also change. Accordingly, if the relation between the ion concentration ratio and the gradient is obtained in advance, a calibration curve of an ion concentration ratio other than the calibration curve (linear expression) that is already acquired can be estimated and, as a result, the concentrations of both ions can be obtained. Note that the computation can be performed using, for example, the LSI 106 or software that functions on a personal computer (PC).

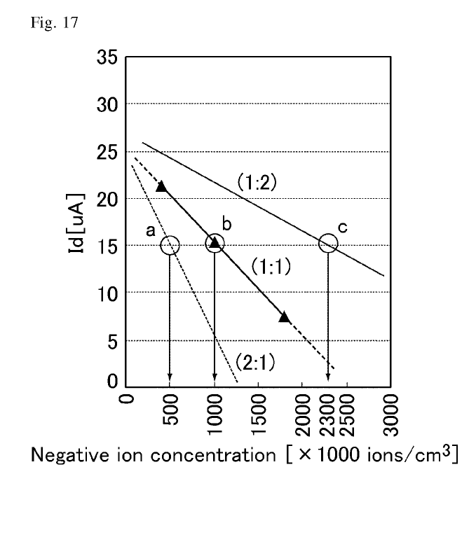

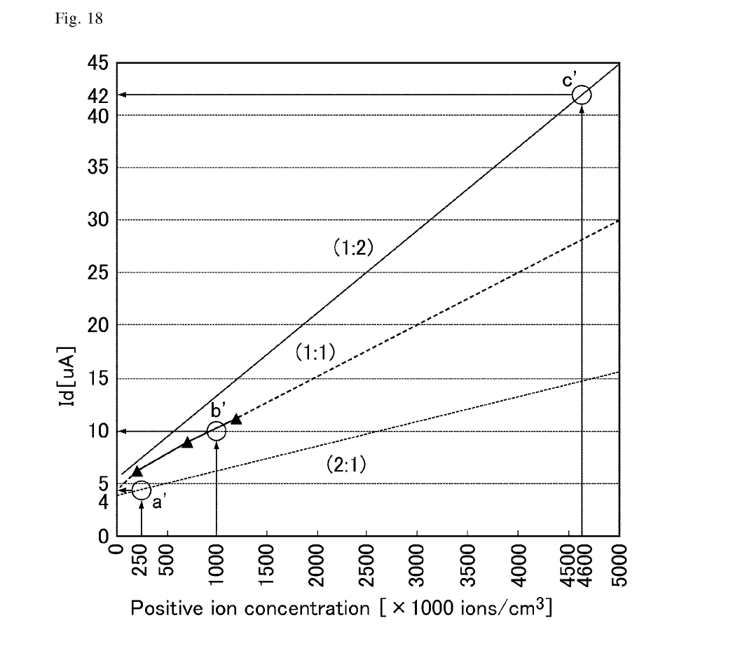

The method for calculating the concentrations of both ions will now be specifically described using FIG. 17 and FIG. 18.

As shown in FIG. 17, when Id(−) that is obtained by an operation to detect negative ions is 15 μA, there are a plurality of intersection points (a, b, c) with the calibration curves.

If the ion ratio is 2:1, the actual concentration ratio should be 500×10³ ions/cm³: 250×10³ ions/cm³, if the ion ratio is 1:1, the actual concentration ratio should be 1000×10³ ions/cm³: 1000×10³ ions/cm³, and if the ion ratio is 2:1, the actual concentration ratio should be 2300×10³ ions/cm³: 4600×10³ ions/cm³.

As shown in FIG. 18, points of intersection (a′, b′, and c′) with the calibration curves are ascertained using values of Id(+) obtained by an operation to detect positive ions. That is, the concentration ratios are ascertained, and as a result the concentrations of both ions are determined.

For example, if Id(+) is 4 μA, since it is known that the ion ratio is 2:1, the negative ion concentration is calculated as 500×10³ ions/cm³ and the positive ion concentration is calculated as 250×10³ ions/cm³. If Id(+) is 10 μA, since it is known that the ion ratio is 1:1, the negative ion concentration is calculated as 1000×10³ ions/cm³ and the positive ion concentration is calculated as 1000×10³ ions/cm³. Further, if Id(+) is 42 μA, since it is known that the ion ratio is 1:2, the negative ion concentration is calculated as 2300×10³ ions/cm³, and the positive ion concentration is calculated as 4600×10³ ions/cm³.

Thus, according to Embodiment 3, with respect to a sample in which both ions are mixed, it is possible to calculate an ion concentration simply and with high accuracy using detection results for positive ions and negative ions.

Further, according to Embodiment 3, since it is possible to measure both ions at the same time, the concentrations of both ions can be measured with higher accuracy than in the case of Embodiment 1 in which one of the negative and positive ions is measured first and thereafter the other of the negative and positive ions is measured.

In addition, since the two sensor TFTs 30 and 30c are N-channel sensor TFTs, the sensor TFTs 30 and 30c can be formed at the same time. Therefore, the manufacturing cost can be reduced more than in the case of Embodiment 2 in which the N-channel sensor TFT 30 and the P-channel sensor TFT 30b are used.

Note that, although the N-channel sensor TFTs 30 and 30c are used in Embodiment 3, P-channel TFTs may also be used. In that case, it is sufficient to push down (lower) the voltage of the node-Z(−) and the node-Z(+), respectively, by means of the push-up/push-down line 23 and 23b.

Further, a push-up or push-down voltage of the node-Z is determined by the expression: (capacitance of capacitor)/(total capacitance of node-Z)×ΔVpp. In this expression, ΔVpp represents a difference between a high voltage of Vrw and a low voltage of Vrw. Therefore, according to the present embodiment, it is possible to employ the following two kinds of parameters to adjust the amount of a voltage increase or voltage decrease of the node-Z(−) and node-Z(+) produced by means of the push-up/push-down lines 23 and 23b. One parameter is the value of ΔVpp for each of Vrw(−) and Vrw(+), and the other parameter is the capacitance of each of the capacitors 43 and 43b. It is thereby possible to easily adjust the node-Z(−) and node-Z(+) to a voltage at which a high Id ratio can be obtained. Further, by adjusting the respective capacitances of the capacitors 43 and 43b, the voltages of Vrw(−) and Vrw(+) can be made the same. That is, a capacitance (C1) of the capacitor 43 and a capacitance (C2) of the capacitor 43b can be set to mutually different values, with C1 being set to an optimal value for detecting negative ions, and C2 being set to an optimal value for detecting positive ions. Further, a waveform (waveform of Vrw(−)) of a pulse voltage applied to the capacitor 43 can be made the same as a waveform (waveform of Vrw(+)) of a pulse voltage applied to the capacitor 43b, and a common power supply can be used for applying Vrw(−) and Vrw(+). Naturally, in a case where C1 and C2 are made mutually different also, it is sufficient to make the waveforms of Vrw(−) and Vrw(+) mutually different and to appropriately adjust the respective push-up voltages of the node-Z(−) and the node-Z(+).

### Embodiment 4

A display device according to Embodiment 4 has the same configuration as Embodiment 3 except for the following points. That is, an ion sensor circuit 407 according to Embodiment 4 includes a negative ion-detecting sensor circuit 401 and a positive ion-detecting sensor circuit 402, and the sensor circuit 401 does not have a push-up/push-down line.

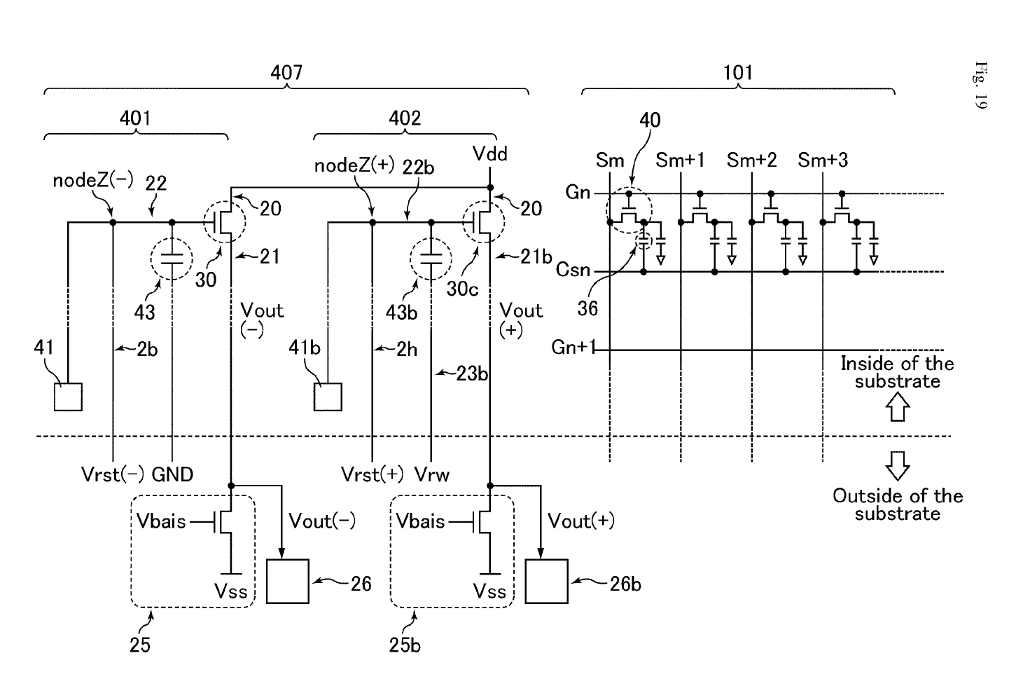

The circuit configuration of the ion sensor circuit 407 according to the present embodiment will now be described using FIG. 19. FIG. 19 is an equivalent circuit that illustrates the ion sensor circuit 407 and one part of the TFT array 101 according to the present embodiment. The display device according to the present embodiment has the same TFT array 101 as Embodiment 1, and hence a description thereof is omitted here.

The ion sensor circuit 407 includes the negative ion-detecting sensor circuit 401 and the positive ion-detecting sensor circuit 402.

First, the negative ion-detecting sensor circuit 401 will be described. The sensor circuit 401 has the same configuration as the sensor circuit 201 of Embodiment 2. A high voltage (+10 V) or a low voltage (0 V) is applied to the input line 20, and the voltage of the input line 20 is taken as Vdd. The voltage of the output line 21 is taken as Vout(−). A point of intersection (node) between the lines 22 and 2b is taken as node-Z(−). A high voltage (+20 V) or a low voltage (−10 V) is applied to the reset line 2b, and the voltage of the reset line 2b is taken as Vrst(−)). A ground (GND) is connected through the capacitor 43 to the connection line 22.

Next, the positive ion-detecting sensor circuit 402 is described. The sensor circuit 402 has the same configuration as the sensor circuit 302 of Embodiment 3. The voltage of the output line 21b is taken as Vout(+). A point of intersection (node) between the lines 22b and 2h is taken as a node-Z(+). A high voltage (+20 V) or a low voltage (−10 V) is applied to the reset line 2b, and the voltage of the reset line 2h is taken as Vrst(+). A high voltage or a low voltage (for example, −10 V) is applied to the push-up/push-down line 23b, and the voltage of the push-up/push-down line 23b is taken as Vrw(+). The high voltage of Vrw(+) can be adjusted to a desired value. Note that the method for changing the value of the power supply described in Embodiment 1 can be used as a method for adjusting the high voltage of Vrw(+) to a desired value.

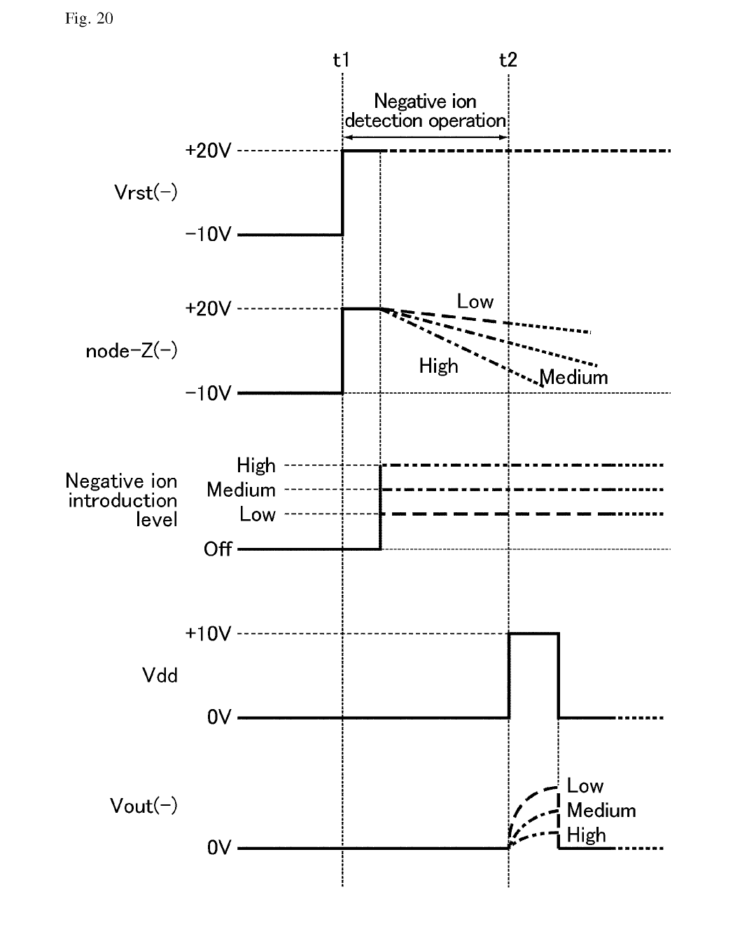

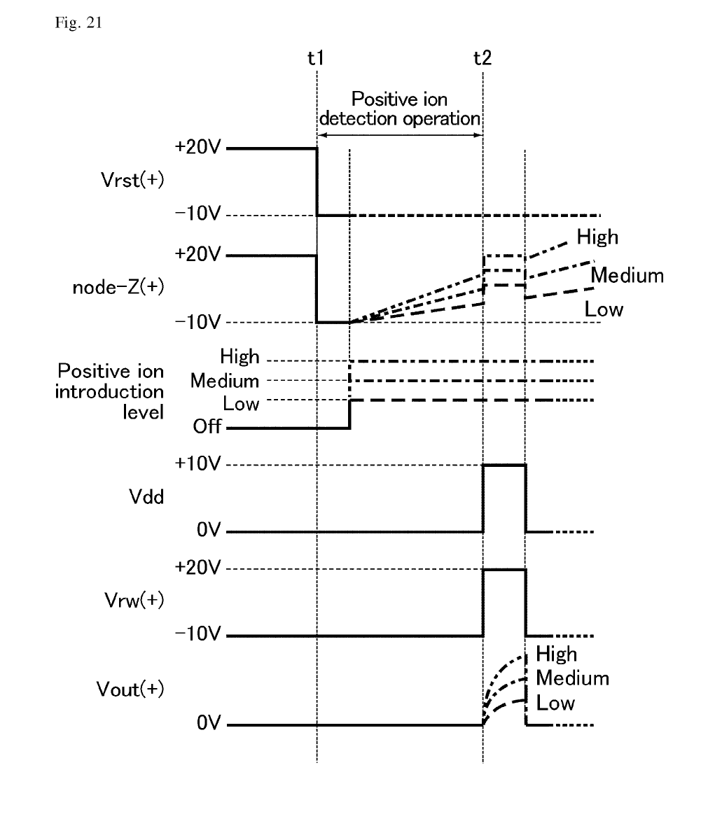

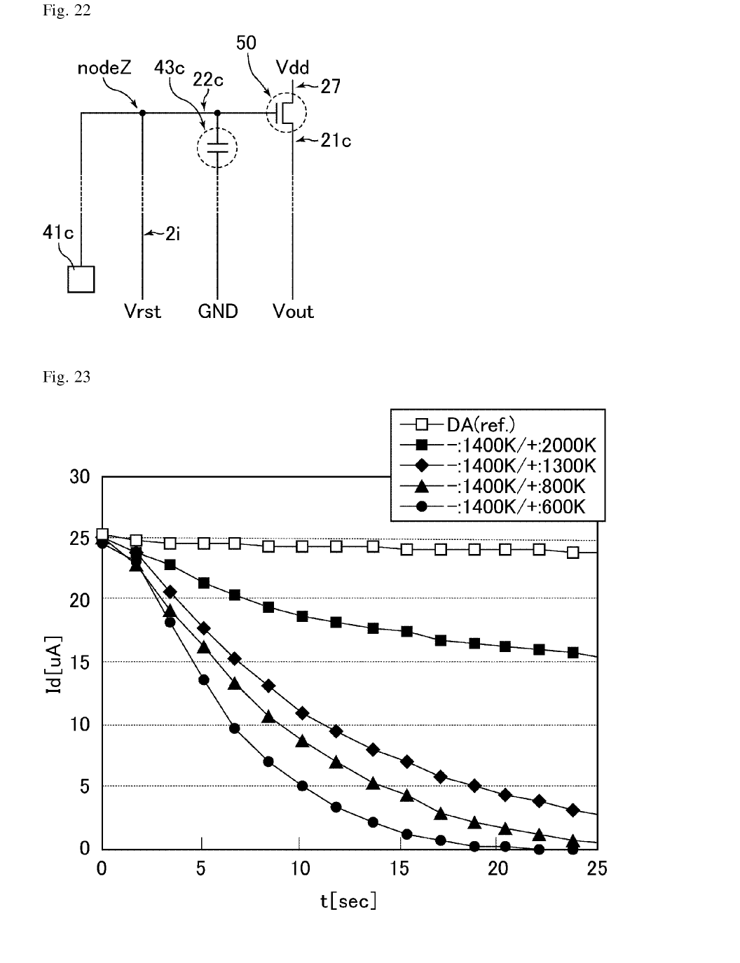

Next, the operational mechanism of the ion sensor circuit will be described in detail using FIG. 20 and FIG. 21. FIG. 20 is a timing chart of the negative ion-detecting sensor circuit according to the present embodiment in the case of detecting negative ions, and FIG. 21 is a timing chart of the positive ion-detecting sensor circuit according to the present embodiment. As shown in FIGS. 20 and 21, the ion sensor circuit 407 performs detection of negative ions using the negative ion-detecting sensor circuit 401 and detection of positive ions using the positive ion-detecting sensor circuit 402 at the same time. First, detection of negative ions will be described.

In the initial state, Vrst(−) is set to a low voltage (−10 V). At this time, a power supply for applying a low voltage (−10 V) to the gate electrode 2e of the pixel TFT 40 can also be used as a power supply for setting Vrst(−) to the low voltage (−10 V). Further, in the initial state, Vdd is set to a low voltage (0 V). Before starting measurement of an ion concentration, at a time t1, first a high voltage (+20 V) is applied to the reset line 2b and the voltage of an antenna 41a (voltage of the node-Z(−)) is reset to +20 V. At this time, a power supply for applying a high voltage (+20 V) to the gate electrode 2e of the pixel TFT 40 can also be used as a power supply for applying Vrst(−). After the voltage of the node-Z(−) has been reset, the reset line 2b is held in a high impedance state. Subsequently, when an operation to introduce ions is commenced and negative ions are collected by the antenna 41a, the voltage of the node-Z(−) that has been reset to +20 V, that is, charged to a positive voltage, is neutralized by the negative ions and decreases (sensing operation). The higher the negative ion concentration is, the faster the speed at which the voltage decreases. At a time t2 that is after a predetermined time period elapses since introduction of ions began, a high voltage (+10 V) is temporarily applied to the input line 20. That is, a pulse voltage of +10 V is applied to the input line 20. Further, the output line 21a is connected to the constant current circuit 25. Accordingly, when a pulse voltage of +10 V is applied to the input line 20, a constant current flows in the input line 20 and the output line 21a. However, the voltage Vout(−) of the output line 21a varies in accordance with the degree of opening of the gate of the sensor TFT 30, that is, the difference in the voltage of the node-Z(−)). The voltage Vout(−) is detected with the ADC 26 as a numerical value for calculating the ion concentration. In this connection, it is also possible to adopt a configuration in which the constant current circuit 25 is not provided, and a current Id(−) of the output line 21a that varies in accordance with the difference in the voltage of the node-Z(−) is detected.

Next, detection of positive ions is described.

In the initial state, Vrst(+) is set to a high voltage (+20 V). At this time, a power supply for applying a high voltage (+20 V) to the gate electrode 2e of the pixel TFT 40 can also be used as a power supply for setting Vrst(+) to the high voltage (+20 V). Further, in the initial state, Vdd is set to a low voltage (0 V). Before starting measurement of an ion concentration, at a time t1, first a low voltage (−10 V) is applied to the reset line 2h and the voltage of the antenna 41b (voltage of the node-Z(+)) is reset to −10 V. At this time, a power supply for applying a low voltage (−10 V) to the gate electrode 2e of the pixel TFT 40 can also be used as a power supply for setting a low voltage (−10 V) in the reset line 2h. After the voltage of the node-Z(+) has been reset, the reset line 2h is held in a high impedance state. Subsequently, when an operation to introduce ions is commenced and positive ions are collected by the antenna 41b, voltage of the node-Z(+) that has been reset to −10 V, that is, charged to a negative voltage, is neutralized by the positive ions and increases (sensing operation). The higher the positive ion concentration is, the faster the speed at which the voltage increases. At a time t2 that is after a predetermined time period has elapsed since introduction of ions began, a high voltage (+10 V) is temporarily applied to the input line 20. That is, a pulse voltage of +10 V is applied to the input line 20. At the same time, an appropriate positive pulse voltage (high voltage) is applied to the push-up/push-down line 23b to push up the voltage of the node-Z(+) through the capacitor 43b. Further, the output line 21b is connected to the constant current circuit 25b.

Accordingly, when a pulse voltage of +10 V is applied to the input line 20, a constant current flows in the input line 20 and the output line 21b. However, a voltage Vout(+) of the output line 21b varies in accordance with the degree of opening of the gate of the sensor TFT 30c, that is, the difference in the voltage of the node-Z(+) that has been pushed up. The voltage Vout(+) is detected with the ADC 26b as a numerical value for calculating the ion concentration. In this connection, it is also possible to adopt a configuration in which the constant current circuit 25b is not provided, and a current Id(+) of the output line 21b that varies in accordance with the difference in the voltage of the node-Z(+) is detected. A positive voltage that is applied to the push-up/push-down line 23b is set in a voltage region of the gate that is suitable for detecting positive ions with high accuracy.

Note that, according to the present embodiment, the high voltage of Vdd is not particularly limited to +10 V, and the high voltage of Vdd may be the same as the high voltage applied to the reset line 2b and 2h, that is, a high voltage of +20 V that is applied to the gate electrode 2e of the pixel TFT 40. It is thereby possible to also use the power supply for applying the high voltage to the gate electrode 2e of the pixel TFT 40 as a power supply for applying the high voltage of Vdd.

Thus, according to Embodiment 4, with respect to a sample in which both ions are mixed, it is possible to calculate an ion concentration simply and with high accuracy using detection results for positive ions and negative ions. The calculation method is as described in the description of Embodiment 3.

Further, according to Embodiment 4, since it is possible to measure both ions at the same time, the concentrations of both ions can be measured with higher accuracy than in the case of Embodiment 1 in which one of the negative and positive ions is measured first and thereafter the other of the negative and positive ions is measured.

In addition, since the two sensor TFTs 30 and 30c are N-channel sensor TFTs, the sensor TFTs 30 and 30c can be formed at the same time. Therefore, the manufacturing cost can be reduced more than in the case of Embodiment 2 in which the N-channel sensor TFT 330 and the P-channel sensor TFT 30b are used.

Further, in Embodiment 4, since the voltage of the node-Z(−) is not adjusted by means of a push-up/push-down line, the manufacturing costs can be suppressed more than in Embodiment 3 in which the voltage of the node-Z(−) is adjusted by means of the push-up/push-down line 23.

Note that, although the N-channel sensor TFTs 30 and 30c are used in Embodiment 4, P-channel TFTs may also be used. In that case, it is sufficient to provide the push-up/push-down line 23 in the negative ion-detecting sensor circuit 401, without providing a push-up/push-down line in the positive ion-detecting sensor circuit 402.

Hereinafter, modification examples of Embodiments 1 to 4 are described.

Although Embodiments 1 to 4 have been described using a liquid crystal display device as an example, a display device of the respective embodiments may be an FPD such as a plasma display or an organic EL display.

Although in Embodiments 1 to 4 ion concentrations are calculated using calibration curves that show the relation between an Id and an ion concentration, for example, an ion concentration may also be calculated by referring to a LUT as shown in FIG. 26. FIG. 26 is an LUT that is referred to when Id(−) is 15 RA. The LUT is a table that includes various combinations of Id(−) and Id(+) as well as combinations of solutions for an ion ratio, a negative ion concentration and a positive ion concentration that correspond to the respective combinations of Id(−) and Id(+) such as, for example, that “when Id(−) is 15 RA and Id(+) is 10 RA, the ion ratio is 1:1, the negative ion concentration is 1000×10³ ions/cm³, and the positive ion concentration is 1000×10³ ions/cm³”. The LUT is stored in a memory (unshown). Note that ion ratios need not be included in the LUT. Further, in a case where it is sufficient to calculate only concentrations of negative ions or of positive ions, concentrations of negative ions or of positive ions need not be included in the LUT.

In addition, similarly to the case of using a calibration curve, since it is unrealistic to acquire an LUT for all combinations of Id(−) and Id(+) in advance, it is preferable to determine Id values between the respective combinations by computation (complementation). It is thereby possible to reduce the size of the memory and simplify the memory task.

The constant current circuit may not be provided. That is, the ion concentration may be calculated by measuring the current between the source and drain of the sensor TFT.

The conduction type of the TFTs formed in the ion sensor 120 and the conduction type of the TFTs formed in the display 130 may be different from each other.

A μc-Si layer, p-Si layer, CG-Si layer, or an oxide semiconductor layer may be used instead of the hydrogenated a-Si layer. Since μc-Si is highly sensitive to light as a-Si is, TFTs including a pc-Si layer are preferably shielded from light. In contrast, p-Si, CG-Si, and an oxide semiconductor have a low sensitivity to light, and thus TFTs including a p-Si layer, CG-Si layer, or oxide semiconductor layer may not be shielded from light.

The type of TFT that is formed on the substrate 1a is not limited to a bottom-gate TFT, and the TFT may be a top-gate TFT or a planar TFT or the like. Further, for example, when a planar TFT is adopted as the sensor TFT, the antenna may be formed over a channel region of the sensor TFT. That is, a configuration may be adopted in which the gate electrode of the sensor TFT is exposed, and the gate electrode itself is caused to function as an ion sensor antenna.

The TFTs formed in the ion sensor 120 and the TFTs formed in the display 130 may be different from each other.

Further, in Embodiments 1 to 4, although the kind of a semiconductor included in a TFT formed in the ion sensor 120 and the kind of a semiconductor included in a TFT formed in the display 130 may be different to each other, from the viewpoint of simplifying the manufacturing process it is preferable that the semiconductors are of the same kind.

The gate driver 103, the source driver 104, and the driving/reading circuit 105 may be monolithic, and directly formed on the substrate 1a.

The above embodiments may be appropriately combined with each other without departing from the scope of the present invention.

The present application claims priority to Patent Application No. 2010-128169 filed in Japan on Jun. 3, 2010 under the Paris Convention and provisions of national law in a designated State, the entire contents of which are hereby incorporated by reference.

### Reference Signs List

1a, 1b: Insulating substrate

2a: Ion sensor antenna electrode

2b, 2h, 2i: Reset line

2c, 2f, 8, 8b: Capacitor electrode

2d, 2e, 2g: Gate electrode

3, 52, 57: Insulating film

4a, 4b, 4c: Hydrogenated a-Si layer

5a, 5b, 5c: n+a-Si layer

6a, 6b, 6c: Source electrode

7a, 7b, 7c: Drain electrode

9: Passivation film

10a, 10b, 10c: Contact hole

11a, 11b, 11c: Transparent conductive film

12a, 12b, 12c: First light-shielding film

13: Color filter

20, 27: Input line

21, 21b, 21c: Output line

22, 22b, 22c: Connection line

23, 23b: Push-up/push-down line

25, 25b: Constant current circuit

26, 26b: Analog-digital conversion circuit (ADC)

30, 30b, 30c: Sensor TFT

31a, 31b: Polarizer

32: Liquid crystal

36: Liquid crystal storage capacitor (Cs)

40: Pixel TFT

41, 41b, 41c: Ion sensor antenna

42: Air ion lead-in/lead-out path

43, 43b, 43c: Capacitor

50: TFT

62, 63, 64: Power supply

65, 66, 67, 68, 69: Switch

101: Display-driving TFT array

103: Gate driver (display scanning signal line-driving circuit)

104: Source driver (display image signal line-driving circuit)

105: Ion sensor driving/reading circuit

106: Arithmetic processing LSI

107, 207, 307, 407: Ion sensor circuit

109: Power supply circuit

110: Display device

120, 125: Ion sensor

130, 135: Display

201, 301, 401: Negative ion-detecting sensor circuit

202, 302, 402: Positive ion-detecting sensor circuit

1. An ion sensor comprising a field effect transistor,
wherein the ion sensor detects one of negative ions and positive ions using the field effect transistor, and consecutively thereafter detects the other of the negative ions and positive ions using the field effect transistor.

2. The ion sensor according to claim 1,
wherein the ion sensor calculates at least one of a negative ion concentration and a positive ion concentration using a detection result for negative ions and a detection result for positive ions.

3. The ion sensor according to claim 2,
wherein the at least one of a negative ion concentration and a positive ion concentration is determined using a previously prepared calibration curve or look-up table.

4. The ion sensor according to claim 1, further comprising
a capacitor,
wherein one terminal of the capacitor is connected to a gate electrode of the field effect transistor, and the other terminal of the capacitor receives voltage.

5. The ion sensor according to claim 4,
wherein the voltage is variable.

6. The ion sensor according to claim 1,
wherein the field effect transistor includes amorphous silicon or microcrystalline silicon.

7. A display device comprising:
an ion sensor according to claim 1;
a display including a display-driving circuit, and
a substrate,
wherein the field effect transistor and at least one portion of the display-driving circuit are formed on the same main surface of the substrate.

8. An ion sensor comprising a first field effect transistor and a second field effect transistor,
wherein the ion sensor detects negative ions using the first field effect transistor and detects positive ions using the second field effect transistor.

9. The ion sensor according to claim 8,
wherein the ion sensor detects positive ions using the second field effect transistor at the same time as detecting negative ions using the first field effect transistor.

10. A display device comprising:
an ion sensor according to claim 8;
a display including a display-driving circuit; and
a substrate,
wherein the first field effect transistor, the second field effect transistor, and at least one portion of the display-driving circuit are formed on the same main surface of the substrate.

11. A method for driving an ion sensor comprising a field effect transistor,
wherein the driving method detects one of negative ions and positive ions using the field effect transistor, and consecutively thereafter detects the other of the negative ions and positive ions using the field effect transistor.

12-15. (canceled)
